(19) United States
(12) Patent Application Publication
(10) Pub. No.: US 2009/0208853 A1
(43) Pub. Date: Aug. 20, 2009

(54) MOTHER SUBSTRATE, FILM FORMATION REGION ARRANGEMENT METHOD, AND COLOR FILTER MANUFACTURING METHOD

(75) Inventor: Kenji SAKAMOTO, Suwa-shi (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/359,529

(22) Filed: Jan. 26, 2009

(30) Foreign Application Priority Data
Feb. 19, 2008 (JP) 2008-036962

(51) Int. Cl. G03F 5/00

(52) U.S. Cl. 430/7

(57) ABSTRACT

A mother substrate for forming a plurality of substrate elements includes a first film formation region and a second film formation region. The first film formation region corresponds to a first substrate element and includes at least one first film formation section. The second film formation region corresponds to a second substrate element and includes at least one second film formation section, the second film formation section having a film formation surface area that is smaller than a film formation surface area of the first film formation section. The second film formation region is disposed in a position closer to a center of rotation of the mother substrate than the first film formation region when the mother substrate is placed on a rotation device of a film formation apparatus during arrangement of a film material on the mother substrate.

### CROSS-REFERENCE TO RELATED APPLICATIONS

This application claims priority to Japanese Patent Application No. 2008-036962 filed on Feb. 19, 2008. The entire disclosure of Japanese Patent Application No. 2008-036962 is hereby incorporated herein by reference.

### BACKGROUND

1. Technical Field

The present invention relates to a mother substrate provided with a plurality of film formation regions, to a method for arranging the film formation regions in the mother substrate, and to a method for manufacturing a color filter provided with a filter region having a filter film.

2. Related Art

Known techniques for forming a color filter film or other functional film of a color liquid crystal device include using a droplet discharge device having a droplet discharge head for discharging droplets of a liquid body to discharge droplets of a liquid body that includes a functional film material so as to land in an arbitrary position on a substrate, whereby the liquid body is arranged in position, and drying the arranged liquid body and forming a functional film. The droplet discharge head of the droplet discharge device used for such film formation is capable of selectively discharging minute droplets from the discharge nozzles thereof and landing the droplets with good positional accuracy, and a film having precise flatness and film thickness can therefore be formed.

In the inkjet line head described in Japanese Laid-Open Patent Application No. 10-166574, the density of discharge nozzles in the secondary scanning direction is increased by aligning the discharge head in the primary scanning direction. Specifically, a line head having high drawing resolution in the secondary scanning direction is obtained by reducing the spacing between discharge nozzles in the secondary scanning direction and reducing the spacing of the discharged liquid body.

The drawing resolution in the primary scanning direction is determined by a discharge interval (hereinafter referred to as the “discharge resolution”) that is determined by the frequency at which the liquid body is discharged, and the speed at which the discharge nozzles and the drawing subject move relative to each other in the primary scanning direction. Japanese Laid-Open Patent Application No. 2006-130469 discloses a droplet discharge method whereby suitably drawing resolution in the drawn region of a drawing subject can be obtained by adjusting the discharge resolution.

### SUMMARY

However, in order to arrange the liquid body with high precision on the substrate using the devices or methods described in the patent documents mentioned above, the substrate must be positioned and set with good precision with respect to the droplet discharge device prior to discharge.

The substrate is positioned by detecting the position of a reference point of the substrate in a coordinate system for specifying the position of the substrate or discharge nozzles that is set in the droplet discharge device, and adjusting the directions of the coordinate axes of the coordinate system for defining the position of the discharge target region in the substrate so as to match the directions of the coordinate axes of the droplet discharge device coordinate system. The directions are adjusted using a rotation device that is capable of rotating the substrate in the directions around perpendicular axes in the coordinate system of the droplet discharge device and the substrate. The set substrate is moved to a position facing the droplet discharge head, and the droplet discharge head and the substrate are moved relative to each other during arrangement of the liquid body.

In order to enable movement, a movable device is generally not completely fixed in the microscopical sense. Since a rotation device is also not in a completely fixed state, slight misalignment in the coordinate axis directions can occur after adjustment is completed in a substrate whose coordinate axis directions have been adjusted by a rotation device. Misalignment of the directions about perpendicular axes in the coordinate system of the substrate causes problems in that the landing position of the discharged liquid body on the substrate can be offset, albeit slightly, from a predetermined position. In the manufacture of high-definition display devices that have recently come to be manufactured, adverse effects on the performance of the product can be caused by the effects of minute positional misalignment on the precision of the shape of the formed film. Since large-sized substrates are used to increase manufacturing efficiency, directional misalignment of the substrate with respect to the droplet discharge device has a significant effect in causing landing position misalignment.

The present invention was developed in order to overcome at least some of the problems described above.

A mother substrate for forming a plurality of substrate elements according to the first aspect includes a first film formation region and a second film formation region. The first film formation region corresponds to a first substrate element and includes at least one first film formation section. The second film formation region corresponds to a second substrate element and includes at least one second film formation section, the second film formation section having a film formation surface area that is smaller than a film formation surface area of the first film formation section. The second film formation region is disposed in a position closer to a center of rotation of the mother substrate than the first film formation region when the mother substrate is placed on a rotation device of a film formation apparatus during arrangement of a film material on the mother substrate.

In this mother substrate, a second film formation region having a second film formation section in which the film formation surface area is smaller than that of the first film formation section is provided in a position closer to the center of rotation of a rotation device provided to a film formation apparatus than the first film formation region in a state in which the mother substrate is set in the film formation apparatus used during arrangement of a film material.

When the rotation device is misaligned in the rotation direction, the amount of positional displacement increases as the distance from the center of rotation increases in the mother substrate rotated by the rotation device. Even given the same amount of positional displacement, the smaller the size of the film formation section, the more likely are adverse effects on the arrangement state of the film material, such as portions of the arranged film material occurring outside the film formation section. A second film formation region having a second film formation section in which the film formation surface area is smaller than that of the first film formation section is provided in a position near the center of rotation, and it is thereby possible to suppress adverse effects on the arrangement state of the film material that are caused by positional displacement due to misalignment in the rotation direction in the rotation device.

In the mother substrate as described above, the first and second film formation sections are preferably configured and arranged to receive the film material discharged from an arrangement head for arranging the film material while the arrangement head and the mother substrate move relative to each other in a primary scanning direction, the first film formation section preferably has a first width in the primary scanning direction and the second film formation section has a second width that is smaller than the first width in the primary scanning direction, and the second film formation region is preferably disposed in a position closer to the center of rotation of the mother substrate than the first film formation region in a secondary scanning direction that is generally perpendicular to the primary scanning direction.

In this mother substrate, the second film formation region, in which the width of the film formation section in the primary scanning direction is a second width, is provided in a position closer in the secondary scanning direction to the center of rotation of the rotation device than the first film formation region, in which the width of the film formation section in the primary scanning direction is a first width that is larger than the second width.

When the rotation device is misaligned in the rotation direction, the amount of positional displacement in the primary scanning direction increases as the distance from the center of rotation in the secondary scanning direction increases in the mother substrate rotated by the rotation device.

Even given the same amount of positional displacement, the smaller the width of the film formation section, the more likely are adverse effects on the arrangement state of the film material, such as portions of the arranged film material occurring outside the film formation section. The second film formation region, in which the width of the film formation section in the primary scanning direction is smaller than that of the first film formation region, is provided in a position closer in the secondary scanning direction to the center of rotation, and it is thereby possible to suppress adverse effects on the arrangement state of the film material that are caused by positional displacement due to misalignment in the rotation direction in the rotation device.

In the mother substrate as described above, the first and second film formation sections are preferably configured and arranged to receive the film material discharged from an arrangement head for arranging the film material while the arrangement head and the mother substrate move relative to each other in a primary scanning direction, the first film formation section preferably has a third width in a secondary scanning direction generally perpendicular to the primary scanning direction, and the second film formation section has a fourth width that is smaller than the third width in the secondary scanning direction, and the second film formation region is preferably disposed in a position closer to the center of rotation of the mother substrate than the first film formation region in the primary scanning direction.

In this mother substrate, the second film formation region, in which the width of the film formation section in the secondary scanning direction is a fourth width, is provided in a position closer in the primary scanning direction to the center of rotation of the rotation device than the first film formation region, in which the width of the film formation section in the secondary scanning direction is a third width that is larger than the fourth width.

When the rotation device is misaligned in the rotation direction, the amount of positional displacement in the secondary scanning direction increases as the distance from the center of rotation in the primary scanning direction increases in the mother substrate rotated by the rotation device.

Even given the same amount of positional displacement, the smaller the width of the film formation section, the more likely are adverse effects on the arrangement state of the film material, such as portions of the arranged film material occurring outside the film formation section. The second film formation region, in which the width of the film formation section in the secondary scanning direction is smaller than that of the first film formation region, is provided in a position closer in the primary scanning direction to the center of rotation, and it is thereby possible to suppress adverse effects on the arrangement state of the film material that are caused by positional displacement due to misalignment in the rotation direction in the rotation device.

In the mother substrate as described above, the second film formation region is preferably disposed in a position closer to a center of the mother substrate than the first film formation region.

In this mother substrate, by providing the second film formation region in a position closer to the center of the mother substrate than the first film formation region, the mother substrate is mounted in the film formation apparatus in a state in which the center of the mother substrate is substantially superposed on the center of rotation, and the second film formation region can thereby be positioned closer to the center of rotation than the first film formation region. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The mother substrate as described above preferably further includes an additional first film formation region and an additional second film formation region. The additional first film formation region is aligned with the first film formation region in the primary scanning direction to form a first region row. The additional second film formation region is aligned with the second film formation region in the primary scanning direction to form a second region row. The second region row is disposed in a position closer to the center of rotation than the first region row in the secondary scanning direction when the mother substrate is placed on the rotation device.

In this mother substrate, first film formation regions in the first region row, and second film formation regions in the second region row extend in the primary scanning direction. Therefore, the film material can be arranged by driving each arrangement head by a specific drive condition corresponding to arranging the film material in the first film formation regions in the first region row or the second film formation regions in the second region row during one cycle of relative movement in the primary scanning direction.

In the mother substrate as described above, the second region row is preferably disposed in a position closer to a center of the mother substrate than the first region row.

In this mother substrate, the second region row is provided in a position closer to the center of the mother substrate than the first region row, and the second film formation regions can thereby be provided in a position closer to the center of the mother substrate than the first film formation regions. The second film formation regions can thereby be provided in a position closer to the center of rotation than the first film formation regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The mother substrate as described above preferably further includes an additional first film formation region and an additional second film formation region. The additional first film formation region is aligned with the first film formation region in the secondary scanning direction to form a third region row. The additional second film formation region is aligned with the second film formation region in the secondary scanning direction to form a fourth region row. The fourth region row is disposed in a position closer to the center of rotation than the third region row in the primary scanning direction when the mother substrate is placed on the rotation device.

In this mother substrate, first film formation regions in the third region row, and second film formation regions in the fourth region row extend in the secondary scanning direction. Therefore, the film material can be arranged by driving a plurality of arrangement heads aligned in the secondary scanning direction by the same drive condition corresponding to arranging the film material in the first film formation regions in the third region row or the second film formation regions in the fourth region row. Since the drive condition is uniform, and the speed of relative movement in the primary scanning direction is the same in all of the plurality of arrangement heads aligned in the secondary scanning direction, it is possible to prevent the work time from being increased by the need to adapt to arrangement heads for which the relative movement is slow.

In the mother substrate as described above, the fourth region row is preferably disposed in a position closer to the center of the mother substrate than the third region row.

In this mother substrate, the fourth region row is provided in a position closer to the center of the mother substrate than the third region row, and the second film formation regions can thereby be provided in a position closer to the center of the mother substrate than the first film formation regions. The second film formation regions can thereby be provided in a position closer to the center of rotation than the first film formation regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

A method for arranging a plurality of film formation regions in a mother substrate for forming a plurality of substrate elements according to a second aspect includes providing a first film formation region corresponding to a first substrate element, and including at least one first film formation section on the mother substrate, and providing a second film formation region corresponding to a second substrate element, and including at least one second film formation section on the mother substrate, the second film formation section having a film formation surface area that is smaller than a film formation surface area of the first film formation section. The providing of the second film formation region includes arranging the second film formation region in a position closer to a center of rotation of the mother substrate than the first film formation region when the mother substrate is placed on a rotation device of a film formation apparatus during arrangement of a film material on the mother substrate.

In this method for arranging film formation regions, the second film formation region provided with a second film formation section in which the film formation surface area is smaller than that of the first film formation section is provided in a position closer to the center of rotation of a rotation device than the first film formation region having the first film formation section in a state in which the mother substrate is set in the film formation apparatus.

When the rotation device is misaligned in the rotation direction, the amount of positional displacement increases as the distance from the center of rotation increases in the mother substrate rotated by the rotation device. Even given the same amount of positional displacement, the smaller the size of the film formation section, the more likely are adverse effects on the arrangement state of the film material, such as portions of the arranged film material occurring outside the film formation section. A second film formation region having a second film formation section in which the film formation surface area is smaller than that of the first film formation section is provided in a position near the center of rotation, and it is thereby possible to suppress adverse effects on the arrangement state of the film material that are caused by positional displacement due to misalignment in the rotation direction in the rotation device.

In the film formation region arrangement method as described above, the providing of the first and second film formation regions preferably includes arranging the first and second film formation sections on the mother substrate to receive the film material discharged from an arrangement head for arranging the film material while the arrangement head and the mother substrate move relative to each other in a primary scanning direction, the providing of the first and second film formation regions preferably includes providing the first film formation section with a first width in the primary scanning direction and the second film formation section with a second width that is smaller than the first width in the primary scanning direction, and the providing of the first and second film formation regions preferably includes arranging the second film formation region in a position closer to the center of rotation of the mother substrate than the first film formation region in a secondary scanning direction that is generally perpendicular to the primary scanning direction.

In this film formation region arrangement method, the second film formation region in which the width of the film formation section in the primary scanning direction is a second width is provided in a position closer to the center of rotation of the rotation device than the first film formation region in which the width of the film formation section in the primary scanning direction is a first width that is larger than the second width in a state in which the mother substrate is set in the film formation apparatus.

When the rotation device is misaligned in the rotation direction, the amount of positional displacement in the primary scanning direction increases as the distance from the center of rotation in the secondary scanning direction increases in the mother substrate rotated by the rotation device.

Even given the same amount of positional displacement, the smaller the width of the film formation section, the more likely are adverse effects on the arrangement state of the film material, such as portions of the arranged film material occurring outside the film formation section. The second film formation region, in which the width of the film formation section in the primary scanning direction is smaller than that of the first film formation region, is provided in a position closer in the secondary scanning direction to the center of rotation, and it is thereby possible to suppress adverse effects on the arrangement state of the film material that are caused by positional displacement due to misalignment in the rotation direction in the rotation device.

In the film formation region arrangement method as described above, the providing of the first and second film formation regions preferably includes arranging the first and second film formation sections on the mother substrate to receive a film material discharged from an arrangement head for arranging the film material while the arrangement head and the mother substrate move relative to each other in a primary scanning direction, the providing of the first and second film formation regions preferably includes providing the first film formation section with a third width in a secondary scanning direction generally perpendicular to the primary scanning direction, and the second film formation section with a fourth width that is smaller than the third width in the secondary scanning direction, and the providing of the first and second film formation regions preferably includes arranging the second film formation region in a position closer to the center of rotation of the mother substrate than the first film formation region in the primary scanning direction.

In this film formation region arrangement method, the second film formation region, in which the width of the film formation section in the secondary scanning direction is a fourth width, is provided in a position closer in the primary scanning direction to the center of rotation of the rotation device than the first film formation region, in which the width of the film formation section in the secondary scanning direction is a third width that is larger than the fourth width.

When the rotation device is misaligned in the rotation direction, the amount of positional displacement in the secondary scanning direction increases as the distance from the center of rotation in the primary scanning direction increases in the mother substrate rotated by the rotation device.

Even given the same amount of positional displacement, the smaller the width of the film formation section, the more likely are adverse effects on the arrangement state of the film material, such as portions of the arranged film material occurring outside the film formation section. The second film formation region, in which the width of the film formation section in the secondary scanning direction is smaller than that of the first film formation region, is provided in a position closer in the primary scanning direction to the center of rotation, and it is thereby possible to suppress adverse effects on the arrangement state of the film material that are caused by positional displacement due to misalignment in the rotation direction in the rotation device.

In the film formation region arrangement method as described above, the providing of the first and second film formation regions preferably includes arranging the second film formation region in a position closer to a center of the mother substrate than the first film formation region.

In this film formation region arrangement method, by providing the second film formation region in a position closer to the center of the mother substrate than the first film formation region, the mother substrate is mounted in the film formation apparatus in a state in which the center of the mother substrate is substantially superposed on the center of rotation, and the second film formation region can thereby be positioned closer to the center of rotation than the first film formation region. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The film formation region arrangement method as described above preferably further includes providing an additional first film formation region aligned with the first film formation region in the primary scanning direction to form a first region row on the mother substrate, and providing an additional second film formation region aligned with the second film formation region in the primary scanning direction to form a second region row on the mother substrate. The providing of the first and second film formation regions and the additional first and second film formation regions includes arranging the second region row in a position closer to the center of rotation than the first region row in the secondary scanning direction when the mother substrate is placed on the rotation device.

In this film formation region arrangement method, first film formation regions in the first region row, and second film formation regions in the second region row extend in the primary scanning direction. Therefore, the film material can be arranged by driving each arrangement head by a specific drive condition corresponding to arranging the film material in the first film formation regions in the first region row or the second film formation regions in the second region row during one cycle of relative movement in the primary scanning direction.

In the film formation region arrangement method as described above, the providing of the first and second film formation regions and the additional first and second film formation regions preferably includes arranging the second region row in a position closer to the center of the mother substrate than the first region row.

In this film formation region arrangement method, the second region row is provided in a position closer to the center of the mother substrate than the first region row, and the second film formation regions can thereby be provided in a position closer to the center of the mother substrate than the first film formation regions. The second film formation regions can thereby be provided in a position closer to the center of rotation than the first film formation regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The film formation region arrangement method as described above preferably further includes providing an additional first film formation region aligned with the first film formation region in the secondary scanning direction to form a third region row on the mother substrate, and providing an additional second film formation region aligned with the second film formation region in the secondary scanning direction to form a fourth region row on the mother substrate. The providing of the first and second film formation regions and the additional first and second film formation regions includes arranging the fourth region row in a position closer to the center of rotation than the third region row in the primary scanning direction when the mother substrate is placed on the rotation device.

In this film formation region arrangement method, first film formation regions in the third region row, and second film formation regions in the fourth region row extend in the secondary scanning direction. Therefore, the film material can be arranged by driving a plurality of arrangement heads aligned in the secondary scanning direction by the same drive condition corresponding to arranging the film material in the first film formation regions in the third region row or the second film formation regions in the fourth region row. Since the drive condition is uniform, and the speed of relative movement in the primary scanning direction is the same in all of the plurality of arrangement heads aligned in the secondary scanning direction, it is possible to prevent the work time from being increased by the need to adapt to arrangement heads for which the relative movement is slow.

In the film formation region arrangement method as described above, the providing of the first and second film formation regions and the additional first and second film formation regions preferably includes arranging the fourth region row in a position closer to the center of the mother substrate than the third region row.

In this film formation region arrangement method, the fourth region row is provided in a position closer to the center of the mother substrate than the third region row, and the second film formation regions can thereby be provided in a position closer to the center of the mother substrate than the first film formation regions. The second film formation regions can thereby be provided in a position closer to the center of rotation than the first film formation regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

A color filter manufacturing method according to a third aspect includes forming a first color element film in a first color element section of a first filter region on a mother substrate, and forming a second color element film in a second color element section of a second filter region with the second color element film having a surface area that is smaller than a surface area of the first color element film. The forming of the first and second color element films includes arranging the second filter region in a position closer to a center of rotation of the mother substrate than the first filter region when the mother substrate is placed on a rotation device of a film formation apparatus during arrangement of a film material on the mother substrate.

In this color filter manufacturing method, the second filter region, having a second color element region in which the formation surface area of the color element film is smaller than the first color element region, is provided in a position closer to the center of rotation of a rotation device than the first filter region having the first color element region in a state in which the mother substrate is set in the film formation apparatus.

When the rotation device is misaligned in the rotation direction, the amount of positional displacement increases as the distance from the center of rotation increases in the mother substrate rotated by the rotation device. Even given the same amount of positional displacement, the smaller the color element region, the more likely are adverse effects on the arrangement state of the color element film material, such as portions of the arranged color element film material occurring outside the color element region. The second filter region, having a second color element region in which the formation surface area of the color element film is smaller than the first color element region, is provided in a position closer to the center of rotation than the first filter region having the first color element region, and it is thereby possible to suppress adverse effects on the arrangement state of the color element film material that are caused by positional displacement due to misalignment in the rotation direction in the rotation device.

In the color filter manufacturing method as described above, the forming of the first and second color element films preferably includes discharging the film material onto the mother substrate from an arrangement head for arranging the film material while the arrangement head and the mother substrate move relative to each other in a primary scanning direction, the forming of the first and second color element films preferably further includes forming the first color element film with a first width in the primary scanning direction and the second color element film with a second width that is smaller than the first width in the primary scanning direction, and the forming of the first and second color element films preferably includes forming the second color element film in a position closer to the center of rotation of the mother substrate than the first color element film in a secondary scanning direction that is generally perpendicular to the primary scanning direction.

In this color filter manufacturing method, the second filter region, in which the width of the color element region in the primary scanning direction is a second width, is provided in a position closer in the secondary scanning direction to the center of rotation of a rotation device than the first filter region, in which the width of the color element region in the primary scanning direction is a first width that is larger than the second width, in a state in which the mother substrate is set in the film formation apparatus.

When the rotation device is misaligned in the rotation direction, the amount of positional displacement in the primary scanning direction increases as the distance from the center of rotation in the secondary scanning direction increases in the mother substrate rotated by the rotation device.

Even given the same amount of positional displacement, the smaller the width of the color element region, the more likely are adverse effects on the arrangement state of the color element film material, such as portions of the arranged color element film material occurring outside the color element region. The second filter region, in which the width of the color element region in the primary scanning direction is smaller than that of the first filter region, is provided in a position closer in the secondary scanning direction to the center of rotation, and it is thereby possible to suppress adverse effects on the arrangement state of the color element film material that are caused by positional displacement due to misalignment in the rotation direction in the rotation device.

In the color filter manufacturing method as described above, the forming of the first and second color element films preferably includes discharging the film material from an arrangement head for arranging the film material while the arrangement head and the mother substrate move relative to each other in a primary scanning direction, the forming of the first and second color element films preferably further includes forming the first color element film with a third width in a secondary scanning direction generally perpendicular to the primary scanning direction, and the second color element film with a fourth width that is smaller than the third width in the secondary scanning direction, and the forming of the first and second color element films preferably includes forming the second color element film in a position closer to the center of rotation of the mother substrate than the first color element film in the primary scanning direction.

In this color filter manufacturing method, the second filter region, in which the width of the color element region in the primary scanning direction is a fourth width, is provided in a position closer in the primary scanning direction to the center of rotation of a rotation device than the first filter region, in which the width of the color element region in the secondary scanning direction is a third width that is larger than the fourth width, in a state in which the mother substrate is set in the film formation apparatus.

When the rotation device is misaligned in the rotation direction, the amount of positional displacement in the secondary scanning direction increases as the distance from the center of rotation in the primary scanning direction increases in the mother substrate rotated by the rotation device.

Even given the same amount of positional displacement, the smaller the width of the color element region, the more likely are adverse effects on the arrangement state of the color element film material, such as portions of the arranged color element film material occurring outside the color element region. The second filter region, in which the width of the color element region in the secondary scanning direction is smaller than that of the first filter region, is provided in a position closer in the primary scanning direction to the center of rotation, and it is thereby possible to suppress adverse effects on the arrangement state of the color element film material that are caused by positional displacement due to misalignment in the rotation direction in the rotation device.

In the color filter manufacturing method as described above, the forming of the first and second color element films preferably includes arranging the first and second color element films on the mother substrate so that the second filter region is disposed in a position closer to the center of the mother substrate than the first filter region.

In this color filter manufacturing method, the second filter region is provided in a position closer to the center of the mother substrate than the first filter region, and the second filter region can thereby be provided in a position closer to the center of rotation than the first filter region by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The color filter manufacturing method as described above preferably further includes forming an additional first color element film in an additional first color element section of an additional first filter region aligned with the first filter region in the primary scanning direction to form a first filter region row, and forming an additional second color element film in an additional second color element section of an additional second filter region aligned with the second filter region in the primary scanning direction to form a second filter region row. The forming of the first and second color element films and the additional first and second color element films preferably includes arranging the second filter region row in a position closer to the center of rotation than the first filter region row in the secondary scanning direction when the mother substrate is placed on the rotation device.

In this color filter manufacturing method, first filter regions in the first region row, and second filter regions in the second region row extend in the primary scanning direction. Therefore, the color element film material can be arranged by driving each arrangement head by a specific drive condition corresponding to arranging the color element film material in the first filter regions in the first region row or the second filter regions in the second region row during one cycle of relative movement in the primary scanning direction.

In the color filter manufacturing method as described above, the forming of the first and second color element films and the additional first and second color element films preferably includes arranging the second filter region row in a position closer to the center of the mother substrate than the first filter region row.

In this color filter manufacturing method, the second filter region row is provided in a position closer to the center of the mother substrate than the first filter region row, and the second film formation regions can thereby be provided in a position closer to the center of the mother substrate than the first film formation regions. The second filter regions can thereby be provided in a position closer to the center of rotation than the first filter regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. Therefore, minimizing the maximum distance from the center of rotation to each portion of the mother substrate makes it possible to reduce the maximum amount of positional displacement caused by misalignment in the rotation direction.

The color filter manufacturing method as described above preferably further includes forming an additional first color element film in an additional first color element section of an additional first filter region aligned with the first filter region in the secondary scanning direction to form a third filter region row, and forming an additional second color element film in an additional second color element section of an additional second filter region aligned with the second filter region in the secondary scanning direction to form a fourth filter region row. The forming of the first and second color element films and the additional first and second color element films preferably includes arranging the fourth filter region row in a position closer to the center of rotation than the third filter region row in the primary scanning direction when the mother substrate is placed on the rotation device.

In this color filter manufacturing method, first filter regions in the third filter region row, and second filter regions in the fourth filter region row extend in the secondary scanning direction. Therefore, the color element film material can be arranged by driving a plurality of arrangement heads aligned in the secondary scanning direction by the same drive condition corresponding to arranging the color element film material in the first filter regions in the third filter region row or the second filter regions in the fourth filter region row. Since the drive condition is uniform, and the speed of relative movement in the primary scanning direction is the same in all of the plurality of arrangement heads aligned in the secondary scanning direction, it is possible to prevent the work time from being increased by the need to adapt to arrangement heads for which the relative movement is slow.

In the color filter manufacturing method as described above, the forming of the first and second color element films and the additional first and second color element films preferably includes arranging the fourth filter region row in a position closer to the center of the mother substrate than the third filter region row.

In this color filter manufacturing method, the fourth filter region row is provided in a position closer to the center of the mother substrate than the third filter region row, and the second film formation regions can thereby be provided in a position closer to the center of the mother substrate than the first film formation regions. The second filter regions can thereby be provided in a position closer to the center of rotation than the first filter regions by mounting the mother substrate in the film formation apparatus in a state in which the center of the mother substrate is substantially superposed on the center of rotation. Placing the mother substrate so that the center thereof is substantially superposed on the center of rotation makes it possible to minimize the maximum value of the distance from the center of rotation to each portion of the mother substrate. When misalignment occurs in the rotation direction, the amount of positional displacement increases as the distance from the center of rotation increases in the mother substrate rotated by the rotation device. It is therefore possible to reduce the maximum amount of positional displacement caused by misalignment in the rotation direction.

### BRIEF DESCRIPTION OF THE DRAWINGS

Referring now to the attached drawings which form a part of this original disclosure:

FIG. 1 is a schematic top plan view showing an overall structure of a droplet discharge device according to an embodiment of the present invention;

FIG. 2 is a schematic side elevational view showing the overall structure of the droplet discharge device;

FIG. 3 includes a diagram (a) illustrating a schematic external perspective view of a droplet discharge head of the droplet discharge device, and a diagram (b) illustrating a schematic plan view of a head unit of the droplet discharge device;

FIG. 4 is a block diagram showing an electrical configuration of the droplet discharge device;

FIG. 5 is a block diagram showing an electrical configuration and signal flow of the droplet discharge heads;

FIG. 6 is a schematic exploded perspective view showing an overall structure of a liquid crystal display panel according to the embodiment of the present invention;

FIG. 7 includes a diagram (a) illustrating a schematic plan view showing a planar structure of an opposing substrate of the liquid crystal display panel, and a diagram (b) illustrating a schematic plan view showing a planar structure of a mother opposing substrate according to the embodiment of the present invention;

FIG. 8 includes a plurality of diagrams (a) to (c) illustrating schematic plan views of examples of the arrangement of the filter films of the tricolor filter;

FIG. 9 is a flowchart showing the process for forming the liquid crystal display panel;

FIG. 10 includes a series of diagrams (a) to (f) illustrating partial cross sectional views of an opposing substrate showing the steps for forming the filter films in the process of forming the liquid crystal display panel;

FIG. 11 includes a series of diagrams (g) to (k) illustrating partial cross sectional views of the opposing substrate showing the steps for forming an alignment film in the process of forming the liquid crystal display panel;

FIG. 12 includes a pair of schematic diagrams (a) and (b) showing the relationship between the landing target region and the shape of the filter film region in different sizes of filter film regions;

FIG. 13 is a flowchart showing the steps for arranging the functional liquid on the mother opposing substrate;

FIG. 14 is a schematic diagram showing the mother opposing substrate mounted on a workpiece mounting stage according to the embodiment of the present invention;

FIG. 15 is a schematic diagram showing a mother opposing substrate mounted on the workpiece mounting stage according to a first modified example;

FIG. 16 is a schematic diagram showing a mother opposing substrate mounted on the workpiece mounting stage according to a second modified example;

FIG. 17 is a schematic diagram showing a mother opposing substrate mounted on the workpiece mounting stage according to a third modified example;

FIG. 18 is a schematic diagram showing a mother opposing substrate mounted on the workpiece mounting stage according to a fourth modified example; and

FIG. 19 is a schematic diagram showing a mother opposing substrate mounted on the workpiece mounting stage according to a fifth modified example.

### DETAILED DESCRIPTION OF EXEMPLARY EMBODIMENTS

Preferred embodiments of the mother substrate, the film formation region arrangement method, and the color filter manufacturing method will be described hereinafter with reference to the drawings. In the embodiments, a mother substrate in which partitions are formed in a substrate having color filters that constitutes a liquid crystal display device is described as an example of the mother substrate, and an example is described of a process for forming a color element film (filter film) or the like that constitutes a color filter using a droplet discharge device as the film formation apparatus. The reduction of the vertical and horizontal scale of members and components is sometimes shown differently than the actual scale for convenience in the drawings referenced in the description below.

### Droplet Discharge Method

The droplet discharge method used to form the filter film or other functional film will first be described. The droplet discharge method has advantages in that there is minimal waste of materials used, and the desired amount of material can be precisely arranged in the desired position. Discharge techniques in a droplet discharge method include a charging control scheme, a pressure vibration scheme, an electromechanical conversion scheme, an electrothermal conversion scheme, an electrostatic attraction scheme, and the like.

Among these example, an electromechanical conversion scheme makes use of the fact that a piezo element (piezoelectric element) deforms when subjected to a pulse electrical signal, and through deformation of the piezo element, pressure is applied via a flexible substance to a space in which a material is stored, and the material is expelled from the space and discharged from a discharge nozzle. Since heat is not applied to a liquid material in a piezo scheme, advantages are gained in that the composition and other characteristics of the material are unaffected, and the size of the droplets can easily be adjusted by adjusting the drive voltage. The piezo scheme described above is used in the present embodiment because there is no effect on the composition and other characteristics of the material, there is a high degree of freedom in the selection of the liquid material, and the droplet control properties are good due to the fact that the size of the droplets can easily be adjusted.

### Droplet Discharge Device

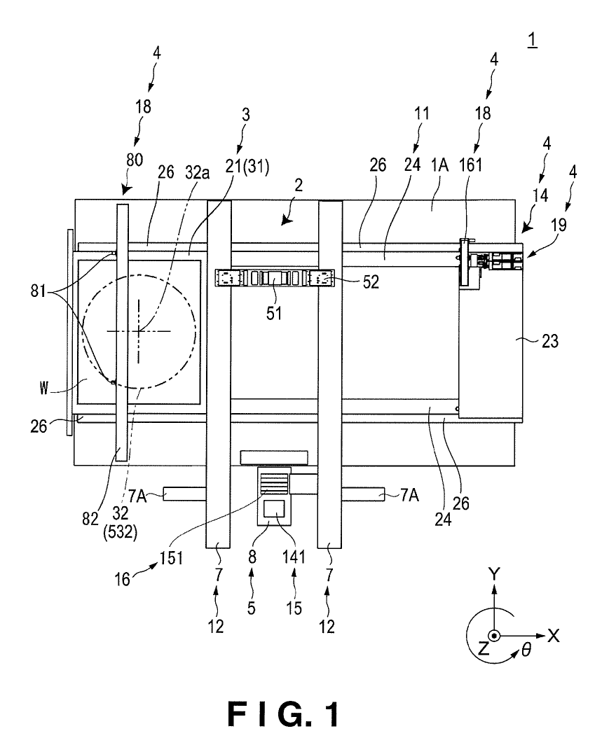

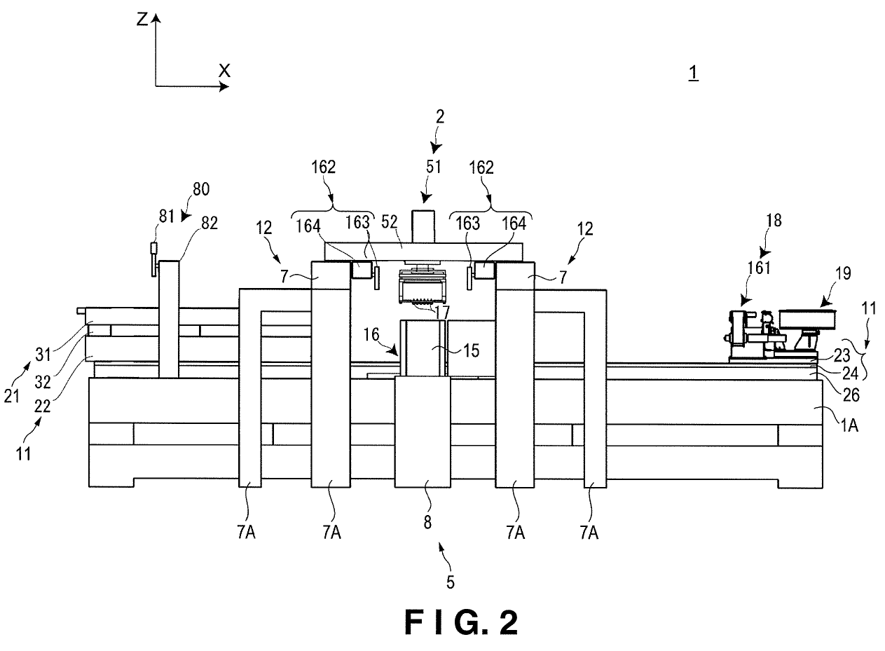

The overall structure of the droplet discharge device 1 will next be described with reference to FIGS. 1 and 2. FIG. 1 is a schematic plan view showing the structure of the droplet discharge device. FIG. 2 is a schematic side view showing the structure of the droplet discharge device.

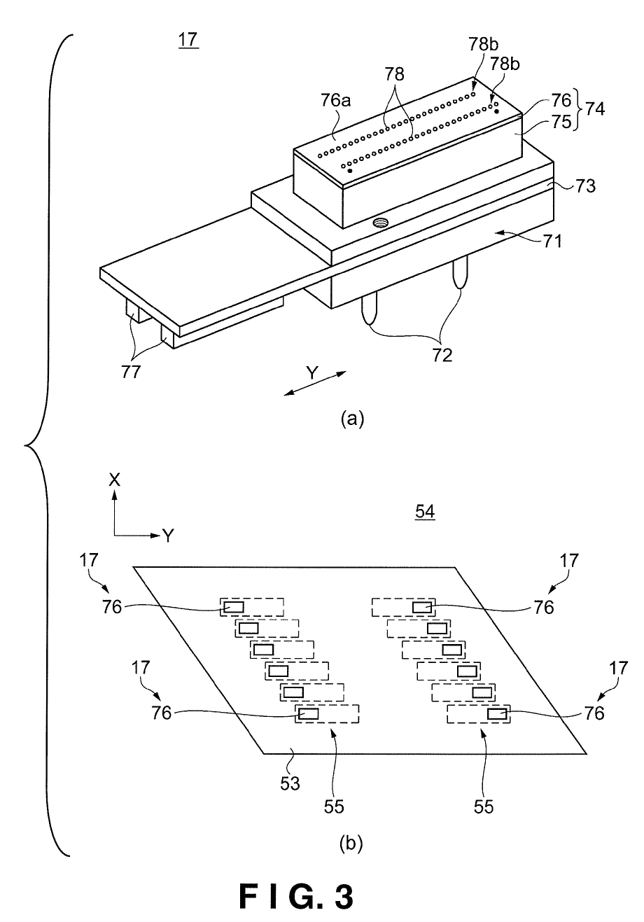

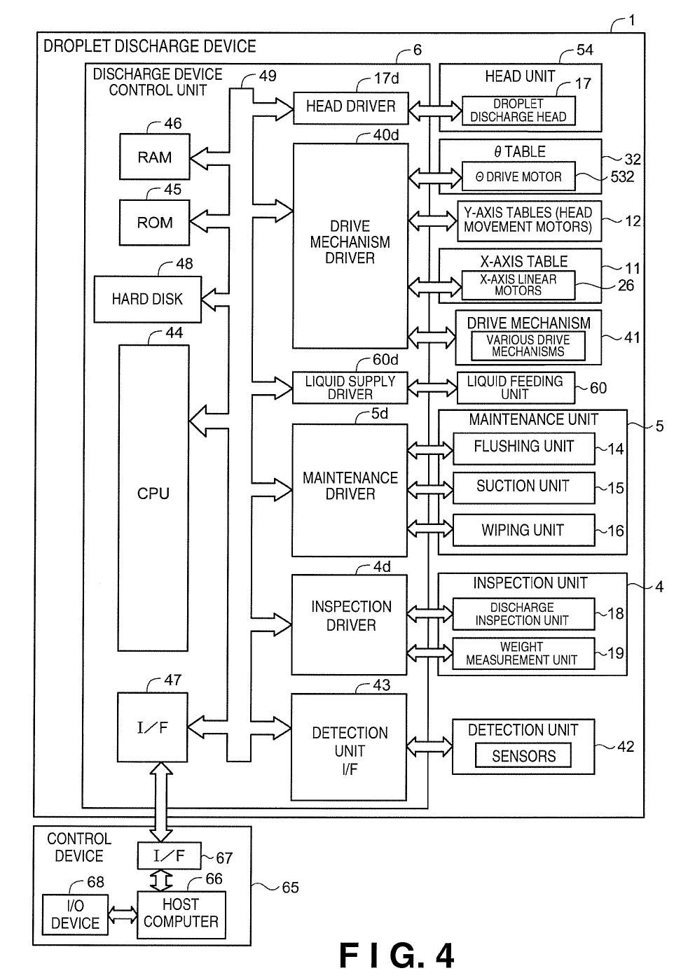

As shown in FIG. 1 or FIG. 2, the droplet discharge device 1 is provided with a discharge unit 2 having a droplet discharge head 17 (see FIG. 3(a)); a workpiece unit 3; a liquid feeding unit 60 (see FIG. 4); a inspection unit 4; a maintenance unit 5; and a discharge device control unit 6 (see FIG. 4).

The discharge unit 2 is provided with twelve droplet discharge heads 17 for discharging droplets of a functional liquid that is a liquid body corresponding to the film material or color element material, and the droplet discharge heads 17 are provided with Y-axis tables 12 for moving the droplet discharge heads 17 and retaining the droplet discharge heads 17 in the position to which the droplet discharge heads 17 are moved. The workpiece unit 3 has a workpiece mounting stage 21 for mounting a workpiece W onto which droplets are discharged from the droplet discharge heads 17. The liquid feeding unit 60 has a storage tank (not shown) for storing the functional liquid, and feeds the functional liquid to the droplet discharge heads 17. The inspection unit 4 has a weight measurement unit 19 and a discharge inspection unit 18 for scanning the state of discharge from the droplet discharge heads 17, and a flushing unit 14 is arranged in the weight measurement unit 19. The maintenance unit 5 has a suction unit 15 and a wiping unit 16 for maintaining the droplet discharge heads 17.

The discharge device control unit 6 performs overall control of the units and other components. Weight measurement, drawing, discharge scanning, maintenance, and other processes performed using the weight measurement unit 19, the discharge unit 2, the discharge inspection unit 18, the maintenance unit 5, or other components are performed through control of each unit or the like by the discharge device control unit 6.

The droplet discharge device 1 is provided with an X-axis support base 1A supported on a stone table, and each unit or other component is provided on the X-axis support base 1A. An X-axis table 11 extends in the X-axis direction that is the primary scanning direction and is provided on the X-axis support base 1A, and the workpiece mounting stage 21 is moved in the X-axis direction (primary scanning direction).

The Y-axis tables 12 of the discharge unit 2 are provided on a pair of Y-axis support bases 7, 7 that are bridged across so as to span the X-axis table 11 via a plurality of supports 7A, and the Y-axis tables 12 extend in the Y-axis direction that is the secondary scanning direction. The discharge unit 2 is provided with a carriage unit 51 that has twelve droplet discharge heads 17. The carriage unit 51 is suspended by a bridge plate 52. The bridge plate 52 is supported by the Y-axis tables 12 via a Y-axis slider (not shown) so as to be able to slide along in the Y-axis direction. The Y-axis tables 12 move the bridge plate 52 (carriage unit 51) in the Y-axis direction (secondary scanning direction).

Functional droplets are discharged by discharge driving of the droplet discharge heads 17 of the discharge unit 2 in synchrony with the driving of the X-axis table 11 and Y-axis tables 12, and an arbitrary drawing pattern is thereby drawn on the workpiece W that is mounted on the workpiece mounting stage 21.

The discharge inspection unit 18 has a scanning drawing unit 161 and imaging units 162. The scanning drawing unit 161 is fixed to an X-axis second slider 23 and configured so as to move integrally with the weight measurement unit 19 and the flushing unit 14 that are also fixed to the X-axis second slider 23. The imaging units 162 have two scanning cameras 163 and camera movement mechanisms 164 for supporting the scanning cameras 163 so that the scanning cameras 163 can slide in the Y-axis direction.

The suction unit 15 and wiping unit 16 provided to the maintenance unit 5 are provided on a stand 8 that is separate from the X-axis table 11 and provided in a position to which the carriage unit 51 can be moved by the Y-axis tables 12. The suction unit 15 has a plurality of divided suction units 141 that apply suction to the droplet discharge heads 17 so that the functional liquid is forcibly expelled from the discharge nozzles 78 (see FIG. 3(a)) of the droplet discharge heads 17. The wiping unit 16 has a wiping sheet 151 onto which a cleaning liquid is sprayed, and wipes off (wipes) the nozzle formation surface 76a (see FIG. 3(a)) of the suctioned droplet discharge heads 17. The suction unit 15 and the wiping unit 16 thus perform maintenance for maintaining or restoring the functioning of the droplet discharge heads 17 of the discharge unit 2.

The X-axis table 11 is provided with an X-axis first slider 22, the X-axis second slider 23, a pair of left and right X-axis linear motors 26, 26, and a pair of X-axis shared support bases 24, 24.

The workpiece mounting stage 21 is attached to the X-axis first slider 22. The X-axis first slider 22 is supported so as to be able to slide in the X-axis direction by the X-axis shared support bases 24 extending in the X-axis direction. The scanning drawing unit 161, the weight measurement unit 19, and the flushing unit 14 are attached to the X-axis second slider 23. The X-axis second slider 23 is supported so as to be able to slide in the X-axis direction by the X-axis shared support bases 24 extending in the X-axis direction. The X-axis linear motors 26 are arranged on the X-axis shared support bases 24, and move the workpiece mounting stage 21 (workpiece W mounted on the workpiece mounting stage 21), the weight measurement unit 19, and other components in the X-axis direction by moving the X-axis first slider 22 or the X-axis second slider 23 along the X-axis shared support bases 24. The X-axis first slider 22 and the X-axis second slider 23 can be driven independently by the X-axis linear motors 26. The X-axis direction corresponds to the primary scanning direction, and the Y-axis direction corresponds to the secondary scanning direction.

The workpiece mounting stage 21 has a suction table 31 for suctioning and setting the workpiece W; a θ table 32 for supporting the suction table 31 and θ-correcting the position of the workpiece W set on the suction table 31 in the θ-axis direction; and other components. The θ table 32 has a θ drive motor 532, and is driven by the θ drive motor 532. The suction table 31 is rotated by the θ table 32 about an axis (θ direction) in the Z-axis direction that passes through the rotation center 32a of the θ table 32 as indicated by the intersection of double-dashed lines in FIG. 1. The θ table 32 corresponds to the rotation device, and the rotation center 32a corresponds to the center of rotation.

The position of the workpiece mounting stage 21 in FIGS. 1 and 2 is the loading and removal position of the workpiece W, and the suction table 31 is moved to this position when the unprocessed workpiece W is introduced (loaded) to the suction table 31, or when the processed workpiece W is recovered (removed). In the loading and removal position, the workpiece W is loaded/unloaded (replaced) with respect to the suction table 31 by a robotic arm (not shown). The unprocessed workpiece W loaded on the suction table 31 is aligned in the loading and removal position using the θ table 32.

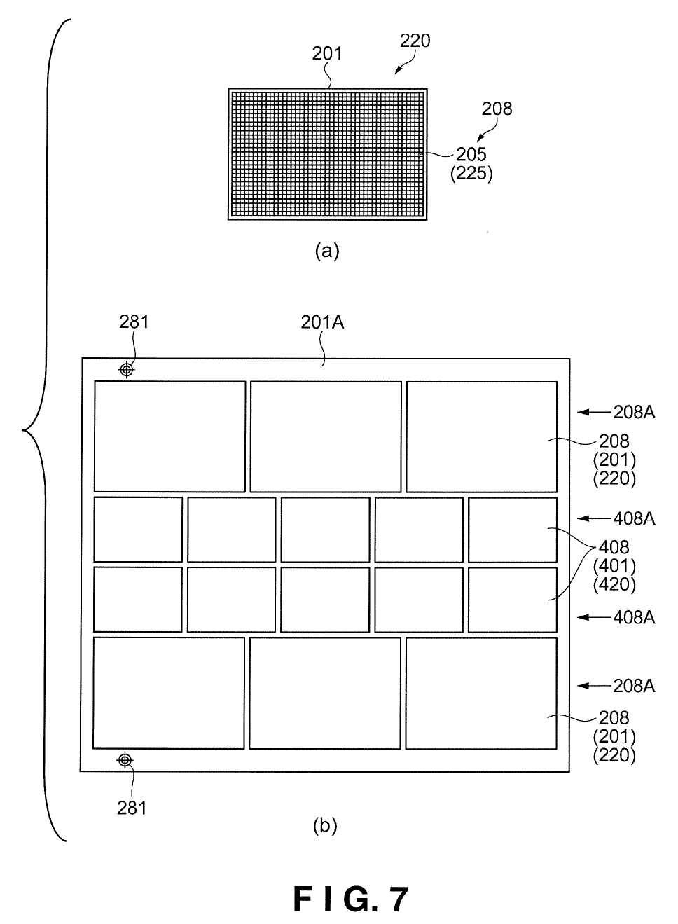

The image recognition unit 80 has a camera movement mechanism 82 and two alignment cameras 81. The camera movement mechanism 82 is provided so as to extend in the Y-axis direction on the X-axis support base 1A and span over the X-axis table 11. The alignment cameras 81 are supported by the camera movement mechanism 82 via camera holders (not shown) so as to be able to slide in the Y-axis direction. The alignment cameras 81 supported by the camera movement mechanism 82 face the X-axis table 11 from above, and are capable of recognizing an image of reference marks (alignment marks) (see FIG. 7) on the workpiece W mounted on the workpiece mounting stage 21 on the X-axis table 11. The two alignment cameras 81 are moved independently of each other in the Y-axis direction by camera movement motors (not shown).

The alignment cameras 81 cooperate with the movement of the workpiece mounting stage 21 in the X-axis direction, and image the alignment marks of various types of workpiece W loaded by the abovementioned robotic arm and recognize the position of various types of workpiece W while being moved in the Y-axis direction by the camera movement mechanism 82. The workpiece W is θ-corrected (aligned) by the θ table 32 on the basis of the imaging results of the alignment cameras 81.

The Y-axis tables 12 are provided with a pair of Y-axis sliders (not shown) and a pair of Y-axis linear motors (not shown). The pair of Y-axis linear motors is mounted on the abovementioned pair of Y-axis support bases 7, 7, and extends in the Y-axis direction. One of the pair of Y-axis sliders is supported by each of the Y-axis support bases 7, 7 so as to be able to slide. The group of Y-axis sliders composed of a Y-axis slider supported by each of the pair of Y-axis support bases 7, 7 straddle-supports the bridge plate 52 to which the carriage unit 51 constituting the discharge unit 2 is fixed. The bridge plate 52 to which the carriage unit 51 constituting the discharge unit 2 is fixed is provided on the pair of Y-axis support bases 7, 7 via the pair of Y-axis sliders for supporting the bridge plate 52 in straddled fashion.

When the pair of Y-axis linear motors are driven (in synchrony), the Y-axis sliders move in parallel in the Y-axis direction at the same time as guided by the pair of Y-axis support bases 7, 7. The bridge plate 52 thereby moves in the Y-axis direction, and the carriage unit 51 suspended by the bridge plate 52 moves in the Y-axis direction.

The carriage unit 51 is provided with a head unit 54 (see FIG. 3(b)) that has twelve droplet discharge heads 17 and a carriage plate 53 (see FIG. 3(b)) for supporting the twelve droplet discharge heads 17 in two groups of six heads each. The head unit 54 is supported so as to be able to raise and lower in the Z-axis direction via a head elevator mechanism (not shown).

### Droplet Discharge Head and Head Unit

The droplet discharge heads 17 and the head unit 54 will next be described with reference to FIGS. 3(a) and 3(b). FIG. 3(a) is a schematic external perspective view showing the droplet discharge head, and FIG. 3(b) is a schematic plan view showing the structure of the head unit.

### Structure of Droplet Discharge Head

As shown in FIG. 3(a), the droplet discharge head 17 is a so-called tandem-type droplet discharge head that is provided with a liquid introduction part 71 having two connecting pins 72, 72; a rectangular head main body 74 that extends to the liquid introduction part 71; and a head base plate 73 that protrudes to the side from between the liquid introduction part 71 and the head main body 74.

The head main body 74 has a pump unit 75 that extends to the liquid introduction part 71, and a nozzle formation plate 76 that extends to the pump unit 75. Discharge nozzles 78 opened in a nozzle formation surface 76a are formed in the nozzle formation plate 76. Two nozzle rows 78b composed of 181 discharge nozzles 78 per row are formed in the droplet discharge head 17. A piezoelectric element (not shown) is provided to the pump unit 75, and by the driving of the piezoelectric element, a functional liquid fed from the liquid introduction part 71 is discharged from the discharge nozzles 78. One piezoelectric element is provided so as to correspond to each discharge nozzle 78, and the functional liquid can be discharged independently by each discharge nozzle 78.

A pair of connectors 77, 77 is provided to the head base plate 73. The connectors 77 are connected to a relay base plate that is connected to the discharge device control unit 6 by a flexible flat cable (FFC cable) or the like, and the droplet discharge head 17 is thereby connected to the discharge device control unit 6.

In the state in which the droplet discharge head 17 is attached to the droplet discharge device 1, the nozzle rows 78b extend in the Y-axis direction. The discharge nozzles 78 that form the two nozzle rows 78b are arranged so as to be offset from each other by one half nozzle pitch in the Y-axis direction. One nozzle pitch is 140 μm, for example. According to design, the droplets discharged from the discharge nozzles 78 that constitute each of the nozzle rows 78b in the same position in the X-axis direction land in a line at equal intervals in the Y-axis direction. When the nozzle pitch of the discharge nozzles 78 is 140 μm, the distance between the centers of the landing positions in the Y-axis direction of the droplets discharged from the two nozzle rows 78b of the droplet discharge head 17 is designed to be 70 μm.

### Head Unit

The overall structure of the head unit 54 of the discharge unit 2 will next be described with reference to FIG. 3(b). The X-axis and Y-axis shown in FIG. 3(b) coincide with the X-axis and Y-axis shown in FIG. 1 when the head unit 54 is attached to the droplet discharge device 1.

As shown in FIG. 3(b), the head unit 54 has the carriage plate 53 and twelve droplet discharge heads 17 that are mounted to the carriage plate 53. The droplet discharge heads 17 are fixed to the carriage plate 53, the head main body 74 is loosely fitted into a hole (not shown) formed in the carriage plate 53, and the nozzle formation plate 76 (head main body 74) protrudes past the surface of the carriage plate 53. FIG. 3(b) is a view from the side of the nozzle formation plate 76 (nozzle formation surface 76a). The twelve droplet discharge heads 17 are divided in the Y-axis direction to form two head groups 55 having six droplet discharge heads 17 each. The nozzle rows 78b of each of the droplet discharge heads 17 extend in the Y-axis direction.

The six droplet discharge heads 17 in one head group 55 are positioned in the Y-axis direction so that the discharge nozzle 78 on the end of one droplet discharge head 17 of mutually adjacent droplet discharge heads 17 is positioned one half nozzle pitch offset from the discharge nozzle 78 on the end of the other droplet discharge head 17. If all of the discharge nozzles 78 in the six droplet discharge heads 17 of the head group 55 were to have the same position in the X-axis direction, the discharge nozzles 78 would be aligned at the same half nozzle pitch interval in the Y-axis direction. Specifically, according to design, the droplets discharged from the discharge nozzles 78 that constitute each of the nozzle rows 78b of the droplet discharge heads 17 in the same position in the X-axis direction land in a line at equal intervals in the Y-axis direction. Since the droplet discharge heads 17 overlap each other in the Y-axis direction, the droplet discharge heads 17 are arranged in staircase fashion in the X-axis direction and form the head groups 55.

### Electrical Structure of Droplet Discharge Device

The electrical structure for driving the droplet discharge device 1 having a structure such as described above will next be described with reference to FIG. 4. FIG. 4 is an electrical structure block diagram showing the electrical structure of the droplet discharge device. The droplet discharge device 1 is controlled by the inputting of data and operation starting, stopping, and other commands via a control device 65 shown in FIG. 4. The control device 65 has a host computer 66 for performing computational processing, and an input/output (I/O) device 68 for inputting and outputting information that is inputted and outputted with respect to the droplet discharge device 1, and the control device 65 is connected to the discharge device control unit 6 via an interface (I/F) 67. The input/output device 68 is a keyboard capable of inputting information, an external input/output device for input/output of information via a storage medium, a storage unit for storing information inputted via an external input/output device, a monitor device, or the like.

The discharge device control unit 6 of the droplet discharge device 1 has an interface (I/F) 47, a CPU (Central Processing Unit) 44, ROM (Read Only Memory) 45, RAM (Random Access Memory) 46, and a hard disk 48. The discharge device control unit 6 of the droplet discharge device 1 also has a head driver 17d, a drive mechanism driver 40d, a liquid supply driver 60d, a maintenance driver 5d, an inspection driver 4d, and a detection unit interface (I/F) 43. These components are electrically connected to each other via a data bus 49.

The interface 47 exchanges data with the control device 65, and the CPU 44 performs various types of computational processing on the basis of commands from the control device 65, and outputs control signals for controlling the operation of each component of the droplet discharge device 1. The RAM 46 temporarily stores control commands or printing data received from the control device 65 in accordance with commands from the CPU 44. The ROM 45 stores routines and the like whereby the CPU 44 performs various types of computational processing. The hard disk 48 stores the control commands or printing data received from the control device 65, and stores the routines and the like whereby the CPU 44 performs various types of computational processing.

The droplet discharge heads 17 of the head unit 54 constituting the discharge unit 2 are connected to the head driver 17d. The head driver 17d drives the droplet discharge heads 17 in accordance with control signals from the CPU 44 and causes droplets of functional liquid to be discharged.

The head movement motors of the Y-axis tables 12, the X-axis linear motors 26 of the X-axis table 11, the θ drive motor 532 of the θ table 32, and drive mechanisms 41 that include various types of drive mechanisms having various types of drive sources are connected to the drive mechanism driver 40d. The various types of drive mechanisms are the camera movement motors of the camera movement mechanisms 164, the camera movement motors for moving the alignment cameras 81, the rotation motor of the suspension mechanism, the elevator motor of the elevator mechanism, and other mechanisms. The drive mechanism driver 40d drives the abovementioned motors and other mechanisms in accordance with control signals from the CPU 44, moves the droplet discharge heads 17 and the workpiece W relative to each other to cause the droplet discharge heads 17 to face an arbitrary position of the workpiece W, and cooperates with the head driver 17d to land droplets of functional liquid in arbitrary positions on the workpiece W.

The suction unit 15 of the maintenance unit 5, the wiping unit 16, and the flushing unit 14 are connected to the maintenance driver 5d. The maintenance driver 5d drives the suction unit 15, the wiping unit 16, or the flushing unit 14 in accordance with control signals from the CPU 44 and causes maintenance of the droplet discharge heads 17 to be performed.

The weight measurement unit 19 and the discharge inspection unit 18 of the inspection unit 4 are connected to the inspection driver 4d. The inspection driver 4d drives the discharge inspection unit 18 or the weight measurement unit 19 in accordance with control signals from the CPU 44 and causes scanning of the discharge state of the droplet discharge head 17 to ascertain the discharge weight, whether discharge has been performed, the landing position accuracy, and the like.

The liquid feeding unit 60 is connected to the liquid supply driver 60d. The liquid supply driver 60d drives the liquid feeding unit 60 in accordance with control signals from the CPU 44 and feeds functional liquid to the droplet discharge heads 17.

A detection unit 42 that includes various types of sensors is connected to the detection unit interface 43. Detection information detected by the sensors of the detection unit 42 is transmitted to the CPU 44 via the detection unit interface 43.

### Functional Liquid Discharge

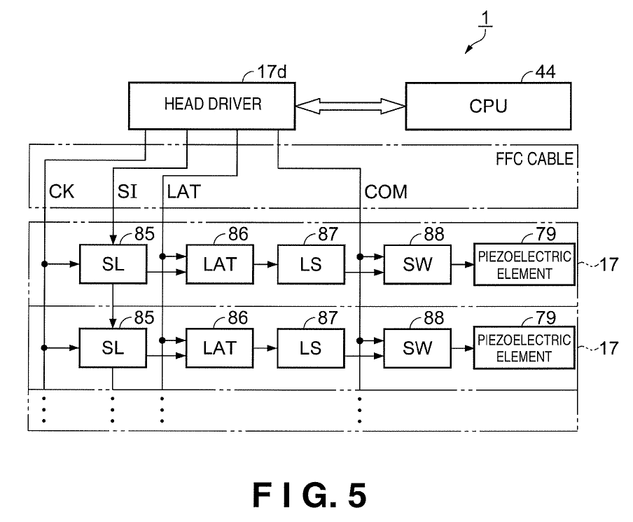

The method of discharge control in the droplet discharge device 1 will next be described with reference to FIG. 5. FIG. 5 is a diagram showing the electrical structure and signal flow of the droplet discharge heads.

As described above, the droplet discharge device 1 is provided with the CPU 44 for outputting control signals for controlling the operation of the components of the droplet discharge device 1, and the head driver 17d for performing electrical drive control of the droplet discharge heads 17.

As shown in FIG. 5, the head driver 17d is electrically connected to the droplet discharge heads 17 via an FFC cable. The droplet discharge heads 17 are also provided with a shift register (SL) 85, a latch circuit (LAT) 86, a level shifter (LS) 87, and a switch (SW) 88 that correspond to a piezoelectric element 79 provided to each discharge nozzle 78 (see FIG. 3).

Discharge control in the droplet discharge device 1 is performed in the following manner. First, the CPU 44 transfers dot pattern data in which an arrangement pattern of the liquid body on the workpiece W or other drawing subject is digitized to the head driver 17d. The head driver 17d then decodes the dot pattern data to generate nozzle data as ON/OFF (discharge/no discharge) information for each discharge nozzle 78. The nozzle data are converted to serial signals (SI), synchronized with a clock signal (CK), and transferred to the shift registers 85.

The nozzle data transferred to the shift registers 85 are latched at the timing at which latch signals (LAT) are inputted to the latch circuits 86, and the nozzle data are converted by the level registers 87 to gate signals used for the switches 88. Specifically, when the nozzle data indicate “ON,” the switches 88 open and drive signals (COM) are fed to the piezoelectric elements 79, and when the nozzle data indicate “OFF,” the switches 88 are closed, and the drive signals (COM) are not fed to the piezoelectric elements 79. The functional liquid is converted to droplets and discharged from nozzles 78 that correspond to “ON,” and the discharged functional liquid is arranged on the workpiece W or other drawing subject.

### Structure of Liquid Crystal Display Panel

The liquid crystal display panel will next be described. The liquid crystal display panel 200 is an example of a liquid crystal device, and is a liquid crystal display panel that is provided with color filters for a liquid crystal display panel that are examples of the color filter.

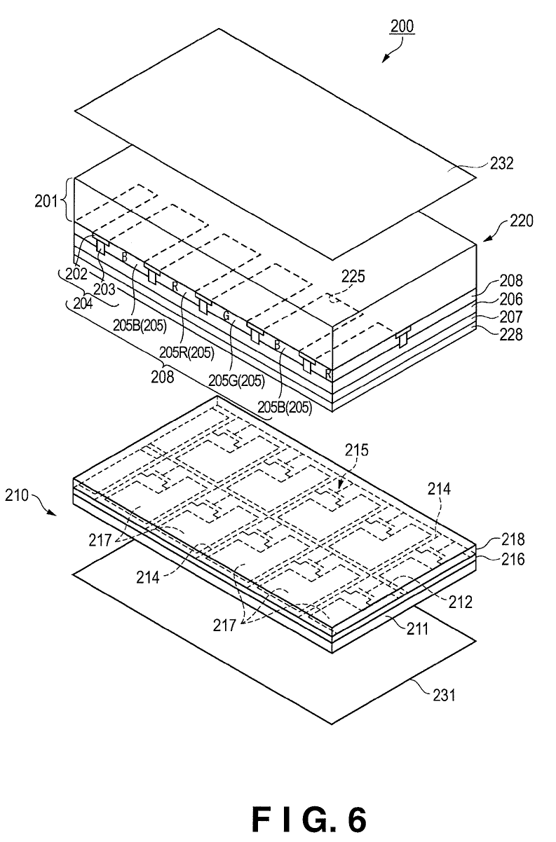

The structure of the liquid crystal display panel 200 will first be described with reference to FIG. 6. FIG. 6 is a schematic exploded perspective view showing the structure of the liquid crystal display panel. The liquid crystal display panel 200 shown in FIG. 6 is an active matrix-type liquid crystal device that uses thin-film transistors (TFT (Thin Film Transistor)) as drive elements, and is a transmissive liquid crystal device that uses a backlight (not shown).

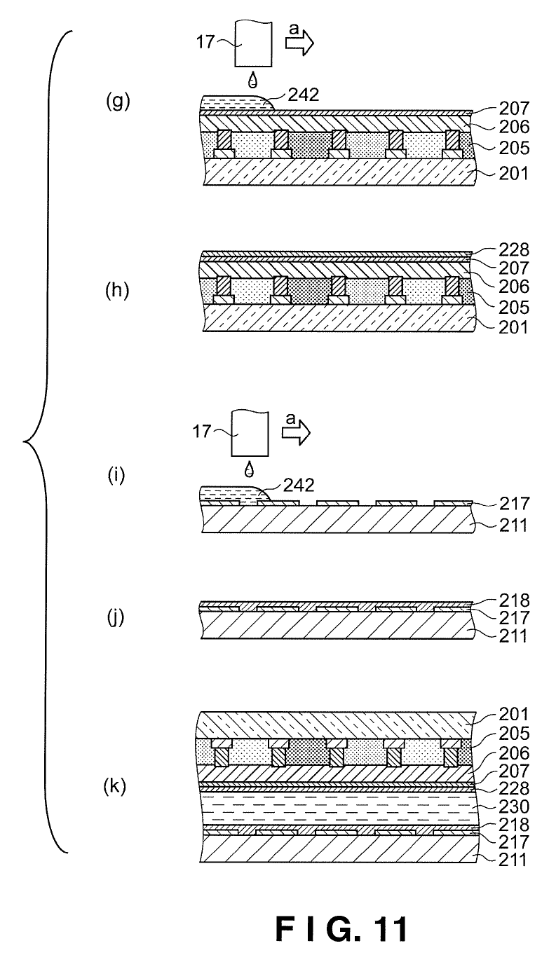

As shown in FIG. 6, the liquid crystal display panel 200 is provided with an element substrate 210 having TFT elements 215; an opposing substrate 220 (a first substrate element) having an opposing electrode 207; and liquid crystals 230 (see FIG. 11(k)) filled into a gap between the element substrate 210 and the opposing substrate 220 that is sealed by a seal member (not shown). A polarizing plate 231 and a polarizing plate 232 are provided to the surfaces on the opposite side of the mutually affixed surfaces of the element substrate 210 and the opposing substrate 220, respectively.

In the element substrate 210, the TFT elements 215, pixel electrodes 217, scanning lines 212, and signal lines 214 are formed on the surface of a glass substrate 211 that faces the opposing substrate 220. An insulation layer 216 is formed so as to fill in the spaces between these elements and conductive films, and the scanning lines 212 and signal lines 214 are formed so as to intersect with each other on either side of the portion in which the insulation layer 216 is formed. The scanning lines 212 and the signal lines 214 are insulated from each other by the portion in which the insulation layer 216 is formed. The pixel electrodes 217 are formed in the regions surrounded by the scanning lines 212 and signal lines 214. The pixel electrodes 217 have a shape in which an angled portion of the rectangular shape is removed from the rectangular shape. The TFT elements 215 equipped with a source electrode, a drain electrode, a semiconductor part, and a gate electrode are incorporated in the portions surrounded by the scanning lines 212, the signal lines 214, and the empty parts of the pixel electrodes 217. The TFT elements 215 are turned on and off by application of signals to the scanning lines 212 and signal lines 214, and control the supply of power to the pixel electrodes 217.

An alignment film 218 for covering the entire region in which the scanning lines 212, the signal lines 214, and the pixel electrodes 217 are formed is provided to the surface of the element substrate 210 adjacent to the liquid crystals 230.

In the opposing substrate 220, a color filter (hereinafter referred to as “CF”) layer 208 is formed on the surface of the glass substrate 201 that faces the element substrate 210. The CF layer 208 has partition walls 204, red filter films 205R, green filter films 205G, and blue filter films 205B. A black matrix 202 for forming the partition walls 204 in a matrix is formed on the glass substrate 201, and banks 203 are formed on the black matrix 202. Rectangular filter film regions 225 are formed by the partition walls 204 that are formed by the black matrix 202 and the banks 203. A red filter film 205R, a green filter film 205G, or a blue filter film 205B is formed in a filter film region 225. The red filter films 205R, the green filter films 205G, and the blue filter films 205B are formed in the shapes and positions that correspond to the pixel electrodes 217 described above.

A planarizing film 206 is provided on the CF layer 208 (on the side of the element substrate 210). An opposing electrode 207 formed from ITO or another transparent conductive material is provided on the planarizing film 206. Providing the planarizing film 206 makes the surface on which the opposing electrode 207 is formed substantially flat. The opposing electrode 207 is a continuous film large enough to cover the entire region in which the pixel electrodes 217 described above are formed. The opposing electrode 207 is connected to wiring formed in the element substrate 210 via conducting parts not shown in the drawing.

An alignment film 228 for covering the entire surface of the pixel electrodes 217 is provided to the surface of the opposing substrate 220 adjacent to the liquid crystals 230. In the state in which the element substrate 210 and the opposing substrate 220 are affixed to each other, the liquid crystals 230 are filled into the space created by the alignment film 228 of the opposing substrate 220, the alignment film 218 of the element substrate 210, and the seal member for affixing the opposing substrate 220 and the element substrate 210 to each other.

The liquid crystal display panel 200 is configured as a transmissive display, but a reflecting layer or semi-transparent reflecting layer may be provided to create a reflective liquid crystal device or a semi-transparent reflective liquid crystal device.

### Mother Opposing Substrate

The mother opposing substrate 201A will next be described with reference to FIG. 7. The opposing substrate 220 is formed by forming the CF layer 208 and other layers on the mother opposing substrate 201A, and by physically dividing the mother opposing substrate 201A into individual opposing substrates 220 (glass substrates 201) before or after the liquid crystal panel 200 is assembled. FIG. 7(a) is a schematic plan view showing the planar structure of the opposing substrate, and FIG. 7(b) is a schematic plan view showing the planar structure of the mother opposing substrate. In the present embodiment, a mother opposing substrate in which CF layers 208 and other layers are formed on the mother opposing substrate 201A, or a mother opposing substrate in which the CF layers 208 and other layers are in the process of being formed is referred to as a mother opposing substrate 201A.

The opposing substrate 220 is formed using a glass substrate 201 composed of transparent quartz glass having a thickness of about 1.0 mm. As shown in FIG. 7(a), the CF layer 208 in the opposing substrate 220 is formed in the portion other than the small edge region that surrounds the glass substrate 201. The CF layer 208 is formed by forming a plurality of filter film regions 225 on the surface of a rectangular glass substrate 201 in a dot pattern, or in a dot matrix pattern in the present embodiment, and forming filter films 205 in the filter film region 225.

As shown in FIG. 7(b), the CF layers 208 of the opposing substrate 220 are formed on the mother opposing substrate 201A, and CF layers 408 constituting opposing substrates 420 (second substrate elements) are also formed in portions that are glass substrates 401. The opposing substrates 420 have essentially the same structure as the opposing substrate 220, and are opposing substrates for forming liquid crystal display panels in which the surface area of the display portion is smaller than that of the liquid crystal display panel 200. When the glass substrates 201 are appropriately arranged on the mother opposing substrate 201A, since there is not enough surface area for only glass substrates 201 to be formed, there is a portion that cannot be used. Therefore, CF layers 408 of glass substrates 401 that are smaller than the glass substrates 201 are formed, and the mother opposing substrate 201A is used without waste by effectively utilizing these portions as glass substrates 401.

A row in which CF layers 208 are arranged in a row will be referred to as a CF layer row 208A, and a row in which CF layers 408 are arranged in a row will be referred to as a CF layer row 408A. In the mother opposing substrate 201A, the CF layer rows 408A are provided closer to the center of the mother opposing substrate 201A than the CF layer rows 208A.

A pair of alignment marks 281, 281 is formed in positions of the mother opposing substrate 201A that are outside the regions in which the CF layers 208 or CF layers 408 are formed. The alignment marks 281 are used as reference marks for positioning the glass substrates 201 during attachment or the like in a manufacturing device in order to execute the steps for forming the CF layers 208 and the like. The mother opposing substrate 201A in the state prior to forming the filter films 205 of the CF layers 208 or CF layers 408 corresponds to the mother substrate or mother base plate.

In FIG. 7, the gaps between the regions in which the CF layers 208 or CF layers 408 are formed are enlarged in order to make the drawing easier to understand, but these gaps are preferably made as small as possible in order to efficiently utilize the mother opposing substrate 201A. The discovery of an arrangement method for efficiently arranging glass substrates of different sizes makes the suitably size setting for the mother opposing substrate 201A apparent and makes it possible also to improve the efficiency with which the mother opposing substrate 201A is extracted from the raw material.

### Color Filters

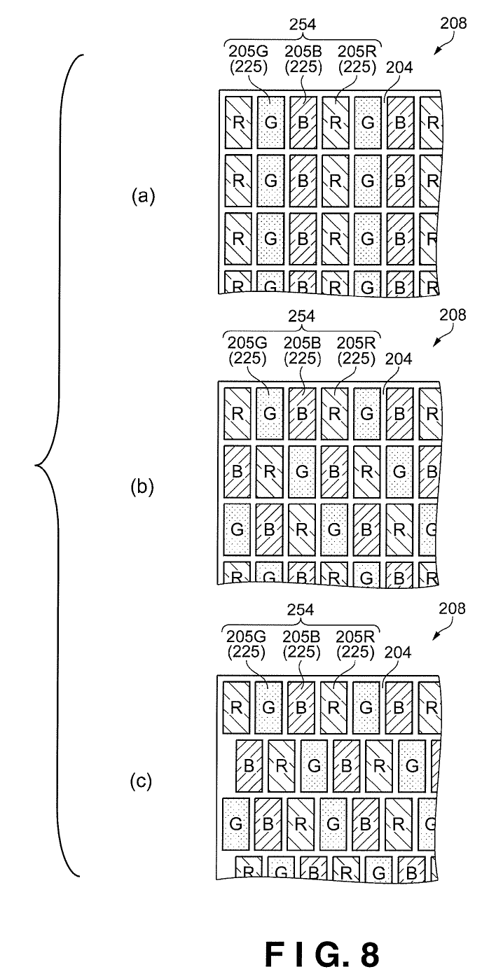

The arrangement of the filter films 205 (red filter films 205R, green filter films 205G, and blue filter films 205B) in the CF layers 208 and CF layers 208 formed on the opposing substrate 220 will next be described with reference to FIG. 8. FIG. 8 is a schematic plan view showing an example of the arrangement of the filter films of the tricolor filter.

As shown in FIG. 8, the filter films 205 are partitioned by partition walls 204 formed in a lattice pattern by a non-transparent resin material, and are formed by filling rectangular (for example) filter film regions 225 arranged in a dot matrix pattern with a color material. For example, by filling the filter film regions 225 with a functional liquid that includes a color material for forming the filter films 205, and evaporating the solvent of the functional liquid to dry the functional liquid, film-shaped filter films 205 are formed that fill the filter film regions 225.

Examples of known arrangements for the red filter films 205R, green filter films 205G, and blue filter films 205B in the tricolor filter include a striped arrangement, a mosaic arrangement, a delta arrangement, and other arrangements. A striped arrangement is one in which the vertical columns of the matrix are all the same-colored red filter films 205R, green filter films 205G, or blue filter films 205B, as shown in FIG. 8(a). A mosaic arrangement is one in which the color changes with each filter film 205 in each line in the horizontal direction, as shown in FIG. 8(b), and in the case of a tricolor filter, any three filter films 205 in a straight line in the vertical or horizontal direction has three colors. The arrangement of filter films 205 is entirely different in a delta arrangement, and in the case of a tricolor filter, any three adjacent filter films 205 have different colors, as shown in FIG. 8(c).

In the tricolor filters shown in FIGS. 8(a), 8(b), and 8(c), the filter films 205 are each formed by a color material in any one of R (red), G (green), and B (blue). A picture element filter (hereinafter referred to as “picture element filter 254”) that is the smallest element for forming an image is formed by a group of filter films 205 that includes one each of a red filter film 205R, a green filter film 205G, and a blue filter film 205B adjacently formed. Full-color display is performed by selectively transmitting light through any one or a combination of the red filter film 205R, green filter film 205G, and blue filter film 205B in a single picture element filter 254 and also adjusting the intensity of the transmitted light.

### Forming Liquid Crystal Display Panel

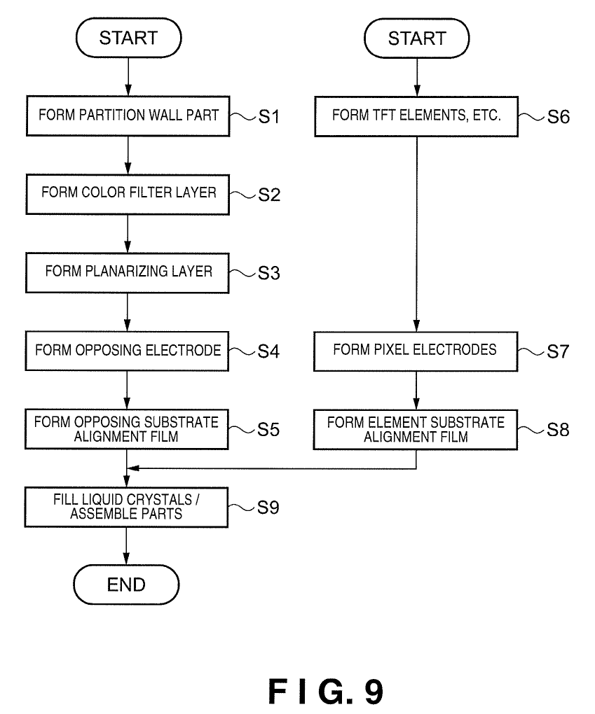

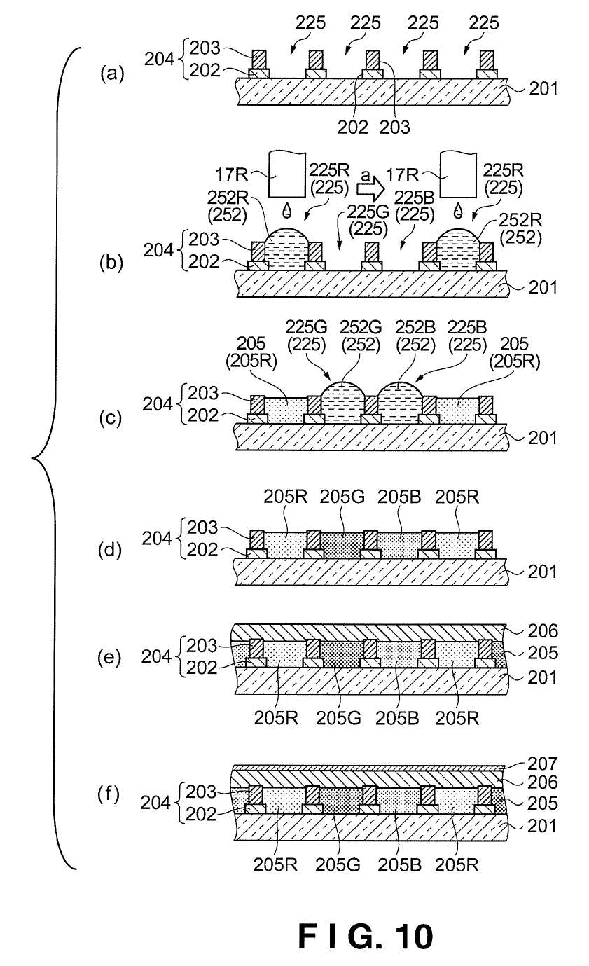

The process for forming the liquid crystal display panel 200 will next be described with reference to FIGS. 9, 10, and 11. FIG. 9 is a flowchart showing the process for forming the liquid crystal display panel. FIG. 10 is a sectional view showing the steps for forming the filter films in the process of forming the liquid crystal display panel, and FIG. 11 is a sectional view showing the steps for forming the alignment film in the process of forming the liquid crystal display panel. The liquid crystal display panel 200 is formed by affixing together the separately formed element substrate 210 and opposing substrate 220.

The opposing substrate 220 is formed by performing step SI through step S5 shown in FIG. 9.

In step S1 of FIG. 9, a partition wall part for partitioning and forming the filter film regions 225 is formed on the glass substrate 201. The partition wall part is formed by forming the black matrix 202 in a lattice pattern, forming the banks 203 thereon, and arranging the partition walls 204 composed of the black matrix 202 and the banks 203 in a lattice pattern. The rectangular filter film regions 225 partitioned by the partition walls 204 are thereby formed on the surface of the glass substrate 201, as shown in FIG. 10(a).

Then, in step S2 of FIG. 9, the materials constituting the red filter films 205R, the green filter films 205G, and the blue filter films 205B are each filled into the filter film regions 225, the red filter films 205R, the green filter films 205G, and the blue filter films 205B are formed, and the CF layer 208 is formed.

More specifically, a red discharge head 17R is brought to face the surface of the glass substrate 201 on which the filter film regions 225 partitioned by the partition walls 204 are formed, as shown in FIG. 10(b). A red functional liquid 252R is discharged toward the filter film regions 225R on which a red filter film 205R is to be formed from the discharge nozzles 78 of the red discharge head 17R, and the red functional liquid 252R is thereby arranged in the filter film regions 225R. At the same time, the red discharge head 17R is moved in the direction indicated by the arrow a with respect to the glass substrate 201, and the red functional liquid 252R is thereby arranged in all of the filter film regions 225R formed on the glass substrate 201. The arranged red functional liquid 252R is dried, and the red filter films 205R are thereby formed in the filter film regions 225R, as shown in FIG. 10(c).

Green functional liquid 252G or blue functional liquid 252B is arranged in the same manner in filter film regions 225G or filter film regions 225B as shown in FIG. 10(c) in order to form the green filter film 205G or blue filter film 205B shown in FIG. 10(b). The green functional liquid 252G or blue functional liquid 252B is dried, and a green filter film 205G or a blue filter film 205B is thereby formed in the filter film regions 225G and filter film regions 225B, as shown in FIG. 10(d). Including the red filter film 205R, a tricolor filter is formed that is composed of a red filter film 205R, a green filter film 205G, and a blue filter film 205B.

In step S3 of FIG. 9, the planarizing layer is formed. As shown in FIG. 10(e), the planarizing film 206 as a planarizing layer is formed on the partition walls 204 and the red filter film 205R, green filter film 205G, and blue filter film 205B that constitute the CF layer 208. The planarizing film 206 is formed in a region that covers the entire surface of at least the CF layer 208. Providing the planarizing film 206 makes the surface on which the opposing electrode 207 is formed substantially flat.

In step S4 of FIG. 9, the opposing electrode 207 is formed. As shown in FIG. 10(f), a thin film is formed using a transparent conductor material on the region on the planarizing film 206 covering the entire surface of at least the region of the CF layer 208 in which the filter films 205 are formed. This thin film is the opposing electrode 207 described above.

The alignment film 228 of the opposing substrate 220 is then formed on the opposing electrode 207 in step S5 of FIG. 9. The alignment film 228 is formed in the region covering the entire surface of at least the CF layer 208.

As shown in FIG. 11(g), a droplet discharge head 17 is brought to face the surface of the glass substrate 201 on which the opposing electrode 207 is formed, and an alignment film liquid 242 is discharged from the droplet discharge head 17 to the surface of the glass substrate 201. At the same time, the droplet discharge head 17 is moved relative to the glass substrate 201 as indicated by the arrow a, and the alignment film liquid 242 is thereby arranged on the entire surface of the region for forming the alignment film 228 of the glass substrate 201. The alignment film 228 is formed as shown in FIG. 11(h) by drying the arranged alignment film liquid 242. Step S5 is performed and the opposing substrate 220 is formed.

The element substrate 210 is formed by executing steps S6 through S8 shown in FIG. 9.

In step S6 of FIG. 9, the TFT elements 215 and other elements, the scanning lines 212, the signal lines 214, the insulation layer 216, and other components are formed by forming conducting layers, insulation layers, or semiconductor layers on the glass substrate 211. The scanning lines 212 and the signal lines 214 are formed in positions facing the partition walls 204, i.e., positions on the periphery of the pixels, in a state in which the element substrate 210 and the opposing substrate 220 are affixed to each other. The TFT elements 215 are formed on the ends of the pixels, and at least one TFT element 215 is formed in each pixel.

The pixel electrodes 217 are then formed in step S7. The pixel electrodes 217 are formed in positions that face the red filter films 205R, the green filter films 205G, and the blue filter films 205B when the element substrate 210 and the opposing substrate 220 are affixed to each other. The pixel electrodes 217 are electrically connected to the drain electrodes of the TFT elements 215.

The alignment film 218 of the element substrate 210 is then formed on the pixel electrodes 217 and other components in step S8. The alignment film 218 is formed in the region that covers the entire surface of at least all of the pixel electrodes 217.

As shown in FIG. 11(i), a droplet discharge head 17 is brought to face the surface of the glass substrate 211 on which the pixel electrodes 217 are formed, and the alignment film liquid 242 is discharged from the droplet discharge head 17 to the surface of the glass substrate 211. At the same time, the droplet discharge head 17 is moved relative to the glass substrate 211 as indicated by the arrow a, and the alignment film liquid 242 is thereby arranged on the entire surface of the region for forming the alignment film 218 of the glass substrate 211. The alignment film 218 is formed as shown in FIG. 11(j) by drying the arranged alignment film liquid 242. Step S8 is executed, and the element substrate 210 is formed.

Then, in step S9 of FIG. 9, the formed opposing substrate 220 and element substrate 210 are affixed together, and the liquid crystals 230 are filled into the intervening space as shown in FIG. 11(k). The polarizing plate 231 and the polarizing plate 232 are then bonded together to assemble the liquid crystal display panel 200. When a plurality of opposing substrates 220 or element substrates 210 is formed in a mother substrate composed of a plurality of glass substrates 201 or glass substrates 211, a mother substrate in which a plurality of liquid crystal display panels 200 is formed is physically divided into individual liquid crystal display panels 200 (substrate elements). Alternatively, step S9 is performed after a step for dividing the mother opposing substrate 201A or mother element substrate into opposing substrates 220 or element substrates 210. Step S9 is performed, and the steps for forming the liquid crystal display panel 200 are completed.

### Landing Target Region

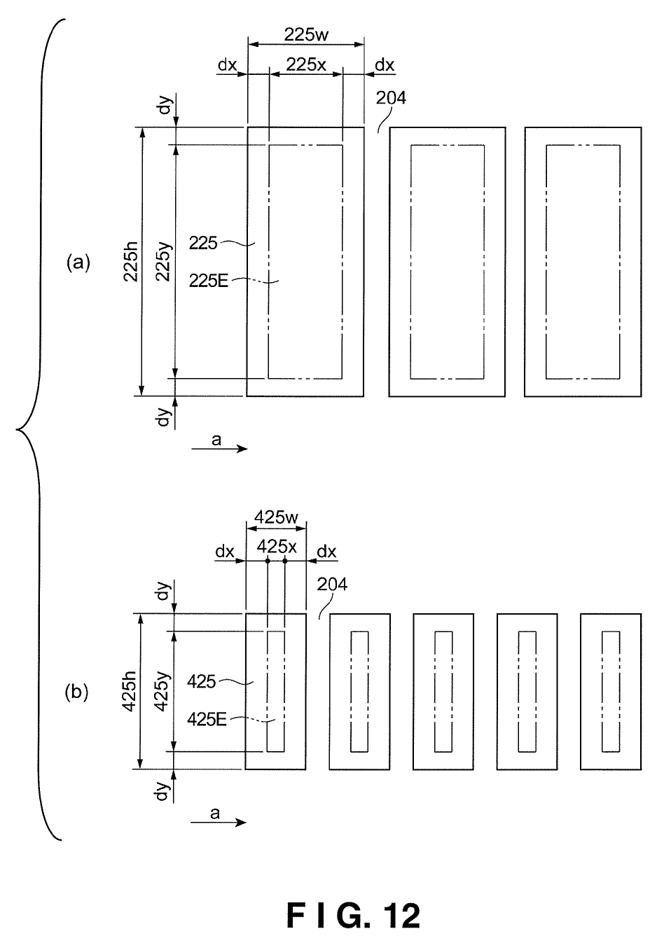

The relationship between the shape of the arrangement region that is the region in which the functional liquid is to be arranged in the drawing subject, and the landing target region that is the region in which the droplets are to be landed in order to arrange the functional liquid in the arrangement region, will next be described with reference to FIG. 12.

The droplets of the functional liquid are discharged so as to land in predetermined positions in the drawing subject, but it is possible for the droplets to land in positions that are offset with respect to the predetermined target position by amounts commensurate with errors caused by various error factors. In order to reliably land the droplets in the arrangement region that is the intended arrangement region, the functional liquid is discharged toward an area for which the error is taken into account so that the droplets land within the arrangement region even when error occurs due to error factors. The area for which error is taken into account is referred to as the landing target region. FIG. 12 is a diagram showing the relationship between the landing target region and the shape of the filter film region.

As described above, in the mother opposing substrate 201A, the CF layers 208 of the opposing substrates 220 are formed, and the CF layers 408 constituting the opposing substrates 420 are also formed in the portions that are the glass substrates 401. FIG. 12(a) shows the size of the landing target region 225E in the filter film region 225 for forming the filter films 205 of the CF layers 208 described above. FIG. 12(b) shows the size of the landing target region 425E in a filter film region 425 for forming the filter films 405 (405R, 405G, 405B) of the CF layers 408 described above. Since the number of filter films 205 in a CF layer 208 and the number of filter films 405 in a CF layer 408 are basically the same, the size of the filter film region 425 of the CF layer 408, which has a smaller surface areas than the CF layer 208, is smaller than the filter film region 225 of the CF layer 208. The horizontal dimension 425w and vertical dimension 425h of the filter film region 425 are about half the horizontal dimension 225w and vertical dimension 225h of the filter film region 225.

The functional liquid is arranged in the filter film region 225 and the filter film region 425 by discharging the functional liquid while moving the discharge nozzles 78 in the direction of the arrow a shown in FIG. 12 with respect to the mother opposing substrate 201A. The direction of the arrow a is the primary scanning direction (X-axis direction), and the direction orthogonal to the direction of the arrow a is the secondary scanning direction (Y-axis direction).

Causes for error in the landing position in the primary scanning direction include error in the flight time of the discharged droplets due to error or fluctuation of the head gap, and error in the rising interval of the latch signal, error in the start time (position) of the latch signal, positional displacement of the filter film region 225 (filter film region 425) (positional displacement of the partition walls 204), and the like.

Causes for error in the landing position in the secondary scanning direction include misalignment (deflection) of the flight direction of the discharged functional liquid in the secondary scanning direction, error in the positional alignment of the discharge nozzles 78 with respect to the mother opposing substrate 201A in the secondary scanning direction, positional displacement of the filter film region 225 (filter film region 425) (positional displacement of the partition walls 204), and the like.

Since the causes of these errors depend on the accuracy of the droplet discharge device 1, the errors are of the same magnitude in the filter film region 225 and the filter film region 425. A margin width dx for absorbing error in the primary scanning direction, and a margin width dy for absorbing error in the secondary scanning direction must be set to the same size for the filter film region 225 and the filter film region 425 when the considered causes for error are the same.

The sizes of the horizontal dimension 425x and the vertical dimension 425y of the landing target region 425E are the sizes of the horizontal dimension 425w and vertical dimension 425h of the filter film region 425 minus the margin width dx or the margin width dy. The sizes of the horizontal dimension 225x and the vertical dimension 225y of the landing target region 225E are the sizes of the horizontal dimension 225w and vertical dimension 225h of the filter film region 225 minus the margin width dx or the margin width dy. The horizontal dimension 425w or vertical dimension 425h is about half of the horizontal dimension 225w or vertical dimension 225h, whereas the horizontal dimension 425x or vertical dimension 425y of the landing target region 425E is from about one third to one fourth of the horizontal dimension 225x or vertical dimension 225y of the landing target region 225E. When the ratio by which the landing target region is smaller than the filter film region increases, it becomes difficult to land enough of the functional liquid in the landing target region to enable the entire area of the filter film region to be filled.

It must be possible to reduce the size of the margin width dx and the margin width dy in order to prevent such dimensions as the horizontal dimension 425x or vertical dimension 425y of the landing target region 425E from decreasing in size. In order to prevent the ratio by which the landing target region decreases in size relative to the filter film region from increasing due to reducing the size of the margin width dx and the margin width dy in the filter film region 425, which is smaller than the filter film region 225, the allowed error for landing position displacement must be reduced. Specifically, the smaller the filter film region is, the more significant the possibility that a highly accurate landing position will be necessary.

After alignment of the mother opposing substrate 201A is completed, when the rotation position is misaligned in the θ table 32, the orientation (angle about the Z-axis) of the mother opposing substrate 201A changes with respect to the droplet discharge device 1. The misalignment of the rotation position in the θ table 32 therefore causes error in the start time (position) of the latch signal, positional displacement of the filter film region 225 (filter film region 425) (positional displacement of the partition walls 204), and the like. Positional displacement of portions of the mother opposing substrate 201A shaken by the misalignment of the rotation position in the θ table 32 increases in proportion to the distance as the distance from the rotation center 32a increases.

### Arrangement of Functional Liquid

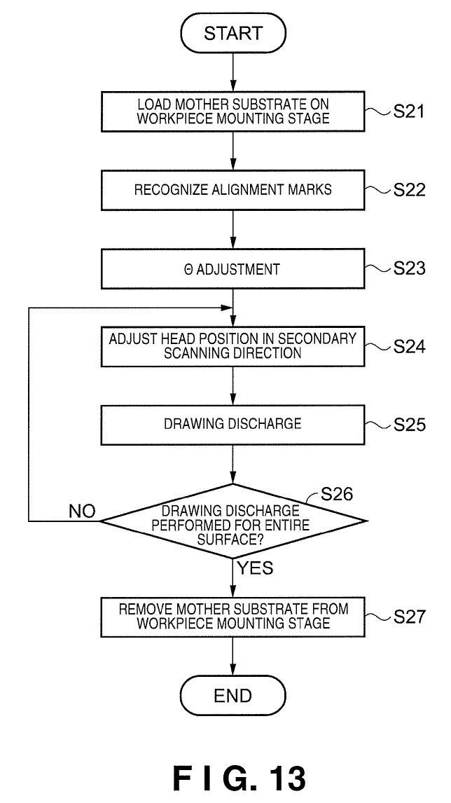

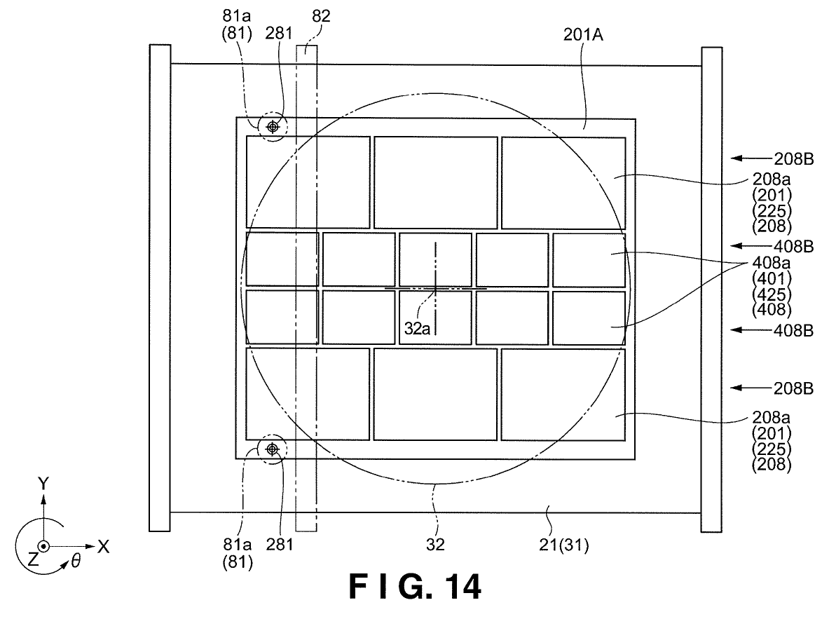

The steps of discharging the functional liquid and arranging the functional liquid in the filter film regions 225 and filter film regions 425 of the CF layers 208 and CF layers 408 in the mother opposing substrate 201A will next be described with reference to FIGS. 13 and 14. The CF layers 208 or CF layers 408 prior to arrangement of the functional liquid will be referred to as the CF layer regions 208a or CF layer regions 408a. FIG. 13 is a flowchart showing the steps for arranging the functional liquid. FIG. 14 is a diagram showing the mother opposing substrate mounted on the workpiece mounting stage and θ-adjusted. The X-axis direction, Y-axis direction, Z-axis direction, and θ direction shown in FIG. 14 coincide with the X-axis direction, Y-axis direction, Z-axis direction, and θ direction shown in FIG. 1.

In step S21 of FIG. 13, the mother opposing substrate 201A is loaded on the workpiece mounting stage 21. More specifically, the workpiece mounting stage 21 is positioned in the loading and removal position for loading and removing the workpiece W. The position of the workpiece mounting stage 21 is strictly determined by the range of positioning accuracy of the X-axis table 11. In the loading and removal position, the mother opposing substrate 201A is mounted in a predetermined direction in a predetermined position on the suction table 31 of the workpiece mounting stage 21 by a robotic arm (not shown), for example, and the mother opposing substrate 201A is suctioned to the suction table 31. The mother opposing substrate 201A is positioned with respect to the droplet discharge device 1 in the range of positioning accuracy of the robotic arm. The mother opposing substrate 201A oriented in a predetermined direction in this case is in the state shown in FIG. 14, in which the four sides of the mother opposing substrate 201A extend in the X-axis direction or the Y-axis direction.

The alignment marks 281 formed on the mother opposing substrate 201A are then recognized by the alignment cameras 81 in step S22. When the mother opposing substrate 201A is already in a predetermined position and a predetermined direction, the alignment marks 281 are also substantially in predetermined positions. As shown in FIG. 14, the alignment marks are therefore within image fields 81a of the alignment cameras 81 that are in predetermined positions, and the alignment marks 281 are recognized by the alignment cameras 81. The alignment marks 281 are recognized by the alignment cameras 81, whereby the discharge device control unit 6 acquires the exact positions of the alignment marks 281.

A case in which the alignment marks 281 cannot be recognized by the alignment cameras 81 is a non-steady state in which the mounting state of the mother opposing substrate 201A is extremely unsuitable, the mother opposing substrate 201A has not been loaded, or the like, and restoration is preferably carried out offline.

The position (orientation) of the θ direction of the mother opposing substrate 201A is then adjusted in step S23. The pair of alignment marks 281, 281 is formed in positions that match each other in the X-axis direction when the four sides of the mother opposing substrate 201A are in predetermined directions that extend in the X-axis direction or Y-axis direction. The position (orientation) of the θ direction of the mother opposing substrate 201A is adjusted to a predetermined orientation in which the extension directions of the four sides coincide with the X-axis direction or Y-axis direction by matching the positions in the X-axis direction of the alignment marks 281 respectively recognized by the pair of alignment cameras 81, 81. Steps S22 and S23 are for aligning the mother opposing substrate 201A.

As described above, the θ direction of the mother opposing substrate 201A is moved by rotating the suction table 31 to which the mother opposing substrate 201A is suctioned about an axis parallel to the Z-axis that passes through the rotation center 32a, through the use of the θ table 32.

The positioning of the alignment marks 281 in the mother opposing substrate 201A for which θ adjustment has been completed is recognized by the discharge device control unit 6 as the positioning of the mother opposing substrate 201A. The respective positions of the filter film region 225 or the filter film region 425 in the CF layer 208a or the CF layer 408a are calculated from the positions of the alignment marks 281 and the specification values of the relative positions with respect to the alignment marks 281.

The position of the droplet discharge heads 17 of the discharge unit 2 in the secondary scanning direction is then adjusted in step S24. The droplet discharge heads 17 are moved in the secondary scanning direction and positioned so as to be in the appropriate position to land the functional liquid in the filter film regions 225 and filter film regions 425 of the mother opposing substrate 201A, for which alignment has been completed. The droplet discharge heads 17 are moved by the Y-axis tables 12 and retained in the appropriate positions for each head unit 54.

In step S25, drawing and discharge are then performed to discharge the functional liquid from the droplet discharge heads 17 to the landing target regions 225E or landing target regions 425E of the filter film regions 225 or filter film regions 425.

Specifically, the mother opposing substrate 201A is moved at a constant speed in the primary scanning direction by moving the workpiece mounting stage 21 in the primary scanning direction through the use of the X-axis table 11. The positions of the alignment marks 281 in the mother opposing substrate 201A for which θ adjustment was completed in step S23 are recognized by the discharge device control unit 6 as the position of the mother opposing substrate 201A. The positions of the alignment marks 281 at a certain time can be determined from the positions recognized by the discharge device control unit 6 and the travel by the X-axis table 11 up to that time. The positions of the landing target regions 225E and landing target regions 425E of the filter film regions 225 and the filter film regions 425 are determined from the positions of the alignment marks 281.

The functional liquid is arranged in the landing target regions 225E and the landing target regions 425E by discharging droplets onto positions specified by dot pattern data from the discharge nozzles 78 of the droplet discharge heads 17 according to the method of discharge control of the droplet discharge device 1 described with reference to FIG. 5. The positions determined from the positions of the alignment marks 281 are used as the positions of the landing target regions 225E and landing target regions 425E in which the functional liquid is actually landed, which correspond to the positions specified by the dot pattern data.

A determination is then made in step S26 as to whether drawing discharge corresponding to the positions specified by the dot pattern data was performed for the entire surface of the mother opposing substrate 201A.

When there is a portion in which drawing discharge was not performed (step S26: NO), the process returns to step S24, the position of the droplet discharge heads 17 is adjusted to a position in which the functional liquid can be discharged into the portion in which drawing discharge was not performed, and steps S25 and S26 are repeated.

When drawing discharge has been performed for the entire surface of the mother opposing substrate 201A (step S26: YES), the process proceeds to step S27.

In step S27 subsequent to step S26, the mother opposing substrate 201A for which drawing discharge was performed is removed from the workpiece mounting stage 21.

Step S27 is performed, and the steps of arranging the functional liquid in the filter film regions 225 and filter film regions 425 of the CF layers 208 and CF layers 408 in the mother opposing substrate 201A are completed.

### Arrangment of CF Layers in Mother Opposing Substrate

The relationship between the position of the rotation center 32a and the arrangement of the CF layers 208 (CF layer rows 208A) and CF layers 408 (CF layer rows 408A) in the mother opposing substrate 201A will next be described with reference to FIG. 14. As described above, in the present embodiment, a mother opposing substrate in which the CF layers 208 and other layers are formed on the mother opposing substrate 201A, or a mother opposing substrate in which the CF layers 208 and other layers are in the process of being formed is referred to as the mother opposing substrate 201A. The X-axis direction, Y-axis direction, Z-axis direction, and θ direction shown in FIG. 14 coincide with the X-axis direction, Y-axis direction, Z-axis direction, and θ direction shown in FIG. 1.

As shown in FIG. 14, in a state in which the mother opposing substrate 201A prior to arrangement of the functional liquid is mounted substantially in a predetermined position of the workpiece mounting stage 21, the rotation center 32a is at the center of the mother opposing substrate 201A. CF region rows 208B in which CF layer regions 208a are arranged in a row, and CF region rows 408B in which CF layer regions 408a are arranged in a row extend in the primary scanning direction. The CF region rows 408B are arranged closer to the center of the mother opposing substrate 201A than the CF region rows 208B. In the state shown in FIG. 14 in which the mother opposing substrate 201A is mounted substantially in a predetermined position of the workpiece mounting stage 21, the CF region rows 408B are provided in positions closer to the rotation center 32a than the CF region rows 208B.

In the steps described above for arranging the functional liquid in the filter film regions 225 and filter film regions 425, the positions of the landing target regions 225E and landing target regions 425E are determined based on the positions of the alignment marks 281 acquired in step S23. Therefore, when the position of the mother opposing substrate 201A in the θ direction is misaligned, there is a difference between the actual positions and the positions of the landing target regions 225E and landing target regions 425E that are recognized by the discharge device control unit 6.

Since the mother opposing substrate 201A is suctioned to and fixed to the suction table 31, misalignment of the mother opposing substrate 201A in the θ direction is created by rotation of the mother opposing substrate 201A about the rotation center 32a of the θ table 32. Consequently, positional displacement of the landing target regions due to misalignment of the mother opposing substrate 201A in the θ direction increases as the distance from the rotation center 32a increases. When positional displacement and the direction of the distance from the rotation center 32a are taken into account, the positional displacement in the primary scanning direction due to misalignment in the θ direction increases as the distance from the rotation center 32a in the secondary scanning direction increases, and positional displacement in the secondary scanning direction due to misalignment in the θ direction increases as the distance from the rotation center 32a in the primary scanning direction increases.

As described with reference to FIG. 12, the filter film regions 425 of the CF layers 408 (CF layer regions 408a) are smaller than the filter film regions 225 of the CF layers 208 (CF layer regions 208a). Therefore, when the same amount of positional displacement has occurred, defects such as the functional liquid being arranged outside of the intended filter regions are more likely to occur in the filter film regions 425 than in the filter film regions 225.

In the mother opposing substrate 201A, the CF region rows 408B are provided closer to the rotation center 32a than the CF region rows 208B, and the positional displacement of the landing target regions 425E when positional displacement (angle misalignment) in the θ direction occurs after alignment is therefore smaller than the positional displacement of the landing target regions 225E. Consequently, the filter film regions 425, which have a higher likelihood of defects when positional displacement occurs, are arranged in the mother opposing substrate 201A so that the amount of positional displacement is reduced.

The filter film regions 225 correspond to first film formation sections, first functional film partitions, or first color element regions, and the filter film regions 425 correspond to second film formation regions, second functional film partitions, or second color element regions. The CF layer regions 208a correspond to first film formation regions, first functional film regions, or first filter regions, and the CF layer regions 408a correspond to second film formation regions, second functional film regions, or second filter regions. The CF region rows 208B correspond to first region rows or first filter region rows, and the CF region rows 408B correspond to second region rows or second filter regions rows.

### First Modified Example of CF Layers in Mother Opposing Substrate

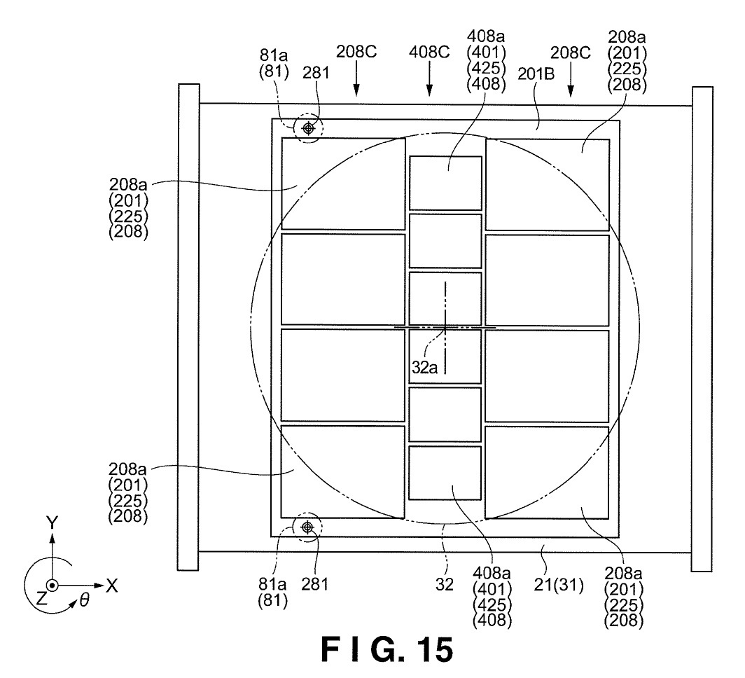

An example of another arrangement of the CF layers in the mother opposing substrate will next be described. The positional relationship between the rotation center 32a and the arrangement of the CF layers 208 (CF layer regions 208a) and CF layers 408 (CF layer regions 408a) in the mother opposing substrate 201B will first be described with reference to FIG. 15. FIG. 15 is a diagram showing the mother opposing substrate having been mounted on the workpiece mounting stage and θ-adjusted. The X-axis direction, Y-axis direction, Z-axis direction, and θ direction shown in FIG. 15 coincide with the X-axis direction, Y-axis direction, Z-axis direction, and θ direction shown in FIG. 1. A mother opposing substrate in which CF layers 208 and other layers are formed on the mother opposing substrate 201B, or a mother opposing substrate in which the CF layers 208 and other layers are in the process of being formed is referred to as a mother opposing substrate 201B, the same as in the case of the mother opposing substrate 201A.

As shown in FIG. 15, the CF layers 208 of the opposing substrate 220 are formed in the mother opposing substrate 201B, and the CF layers 408 that constitute the opposing substrates 420 are formed in the portions that are the glass substrates 401. As described above, the opposing substrates 420 provided with the CF layers 408 have essentially the same structure as the opposing substrates 220 and are opposing substrates for forming liquid crystal display panels that have a smaller surface area than a liquid crystal display panel 200.

A pair of alignment marks 281, 281 the same as those of the mother opposing substrate 201A are formed in positions that are outside the regions in which the CF layers 208 or CF layers 408 are formed in the mother opposing substrate 201B. The alignment marks 281 are used as reference marks for positioning at such times as when the mother opposing substrate 201B is attached to the droplet discharge device 1 or other manufacturing device in order to perform the steps for forming the CF layers 208 and other layers.

In FIG. 15, the gaps between the CF layer regions 208a or CF layer regions 408a are enlarged in order to make the drawing easier to understand, but these gaps are preferably made as small as possible in order to efficiently utilize the mother opposing substrate 201B.

In a state in which the mother opposing substrate 201B prior to arrangement of the functional liquid is mounted substantially in a predetermined position of the workpiece mounting stage 21, the rotation center 32a is at the center of the mother opposing substrate 201B. CF region rows 208C in which CF layer regions 208a are arranged in a row, and CF region rows 408C in which CF layer regions 408a are arranged in a row extend in the secondary scanning direction. The CF region rows 408C are arranged closer to the center of the mother opposing substrate 20B than the CF region rows 208C. In the state shown in FIG. 15 in which the mother opposing substrate 201B is mounted substantially in a predetermined position of the workpiece mounting stage 21, the CF region rows 408C are provided in positions closer to the rotation center 32a than the CF region rows 208C.

Positional displacement of the landing target regions due to misalignment of the mother opposing substrate 201B in the θ direction increases as the distance from the rotation center 32a increases, the same as in the case of the mother opposing substrate 201A described above.

The filter film regions 425 of the CF layers 408 (CF layer regions 408a) are smaller than the filter film regions 225 of the CF layers 208 (CF layer regions 208a). Therefore, when the same amount of positional displacement has occurred, defects such as the functional liquid being arranged outside of the intended filter regions are more likely to occur in the filter film regions 425 than in the filter film regions 225.

In the mother opposing substrate 201B, the CF region rows 408C are provided closer to the rotation center 32a than the CF region rows 208C, and the positional displacement of the landing target regions 425E when positional displacement (angle misalignment) in the θ direction occurs after alignment is therefore smaller than the positional displacement of the landing target regions 225E. Consequently, the filter film regions 425, which have a higher likelihood of defects when positional displacement occurs, are arranged in the mother opposing substrate 201B so that the amount of positional displacement is reduced.

The CF layer regions 208a in the mother opposing substrate 201B correspond to first film formation regions, first functional film regions, or first filter regions, and the CF layer regions 408a correspond to second film formation regions, second functional film regions, or second filter regions. The CF region rows 208C correspond to third region rows or third filter region rows, and the CF region rows 408C correspond to fourth region rows or fourth filter region rows. The mother opposing substrate 201B in the state prior to forming the filter films 205 of the CF layers 208 and CF layers 408 corresponds to a mother substrate or a mother base plate.

### Second Modified Example of CF Layers INT Mother Opposing Substrate

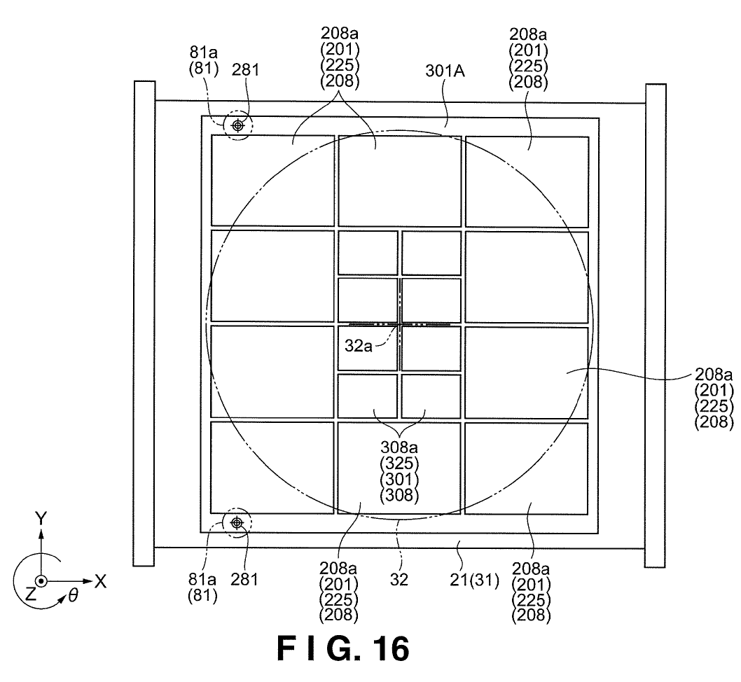

The positional relationship between the rotation center 32a and the arrangement of the CF layers 208 (CF layer regions 208a) and CF layers 308 (CF layer regions 308a) in the mother opposing substrate 301A will next be described with reference to FIG. 16. FIG. 16 is a diagram showing the mother opposing substrate having been mounted on the workpiece mounting stage and θ-adjusted. The CF layers 308 prior to arranging the functional liquid are referred to as CF layer regions 308a, the same as in the case of the CF layer regions 208a for the CF layers 208. A mother opposing substrate in which CF layers 208, CF layers 308, and other layers are formed on the mother opposing substrate 301A, or a mother opposing substrate in which the CF layers 208, CF layers 308, and other layers are in the process of being formed is referred to as a mother opposing substrate 301A, the same as in the case of the mother opposing substrate 201A and other mother opposing substrate described above.

As shown in FIG. 16, the CF layers 208 of the opposing substrate 220 are formed in the mother opposing substrate 301A, and the CF layers 308 that constitute opposing substrates that differ from the opposing substrates 220 are formed in the portions that are the glass substrates 301. The opposing substrates provided with the CF layers 308 have essentially the same structure as the opposing substrates 220 and are opposing substrates for forming liquid crystal display panels that have a smaller surface area than a liquid crystal display panel 200.

A pair of alignment marks 281, 281 the same as those of the mother opposing substrate 201A are formed in positions that are outside the regions in which the CF layers 208 or CF layers 308 are formed in the mother opposing substrate 301A. The alignment marks 281 are used as reference marks for positioning at such times as when the mother opposing substrate 301A is attached to the manufacturing device in order to perform the steps for forming the CF layers 208 and other layers.

In FIG. 16, the gaps between the CF layer regions 208a or CF layer regions 308a are enlarged in order to make the drawing easier to understand, but these gaps are preferably made as small as possible in order to efficiently utilize the mother opposing substrate 301A.

The rotation center 32a is at the center of the mother opposing substrate 301A in a state in which the mother opposing substrate 301A is mounted substantially in a predetermined position of the workpiece mounting stage 21 prior to arrangement of the functional liquid. Eight CF layer regions 308a are arranged in the center of the mother opposing substrate 301A. The CF layer regions 208a are arranged on the periphery of the mother opposing substrate 301A so as to surround the eight CF layer regions 308a. In the state shown in FIG. 16 in which the mother opposing substrate 301A is mounted substantially in a predetermined position of the workpiece mounting stage 21, the CF layer regions 308a are provided in positions closer to the rotation center 32a than the CF layer regions 208a.

In the steps described above for arranging the functional liquid in the filter film regions 225 and filter film regions 425, the positions of the landing target regions 225E and landing target regions 425E are determined based on the positions of the alignment marks 281 acquired in step S22. In the same manner, in the steps for arranging the functional liquid in the filter film regions 225, and the filter film regions 325 of the CF layer regions 308a, the positions of the landing target regions of the filter film regions 225 and the filter film regions 325 are determined based on the acquired positions of the alignment marks 281. Therefore, when the position of the mother opposing substrate 301A in the θ direction is misaligned, there is a difference between the actual positions and the positions of the landing target regions of the filter film regions 225 and filter film regions 325 that are recognized by the discharge device control unit 6. Since the mother opposing substrate 301A is suctioned to and fixed to the suction table 31, misalignment of the mother opposing substrate 301A in the θ direction is created by rotation of the mother opposing substrate 301A about the rotation center 32a of the θ table 32. Consequently, positional displacement of the landing target regions due to misalignment of the mother opposing substrate 301A in the θ direction increases as the distance from the rotation center 32a increases.

As described above, the filter film regions 325 of the CF layers 308 (CF layer regions 308a) are smaller than the filter film regions 225 of the CF layers 208 (CF layer regions 208a). Therefore, when the same amount of positional displacement has occurred, defects such as the functional liquid being arranged outside of the intended filter regions are more likely to occur in the filter film regions 325 than in the filter film regions 225.

In the mother opposing substrate 301A, the CF layer regions 308a are provided closer to the rotation center 32a than the CF layer regions 208a, and the positional displacement of the landing target regions of the filter film regions 325 when positional displacement (angle misalignment) in the θ direction occurs after alignment is therefore smaller than the positional displacement of the landing target regions of the filter film regions 225. Consequently, the filter film regions 325, which have a higher likelihood of defects when positional displacement occurs, are arranged in the mother opposing substrate 301A so that the amount of positional displacement is reduced.

The filter film regions 225 correspond to first film formation sections, first functional film partitions, or first color element regions, and the filter film regions 325 correspond to second film formation sections, second functional film partitions, or second color element regions. The CF layer regions 208a correspond to first film formation regions, first functional film regions, or first filter regions, and the CF layer regions 308a correspond to second film formation regions, second functional film regions, or second filter regions. The mother opposing substrate 301A prior to forming the filter films 205 of the CF layers 208 and CF layers 308 corresponds to a mother substrate or mother base plate.

### Third Modified Example of CF Layers in Mother Opposing Substrate

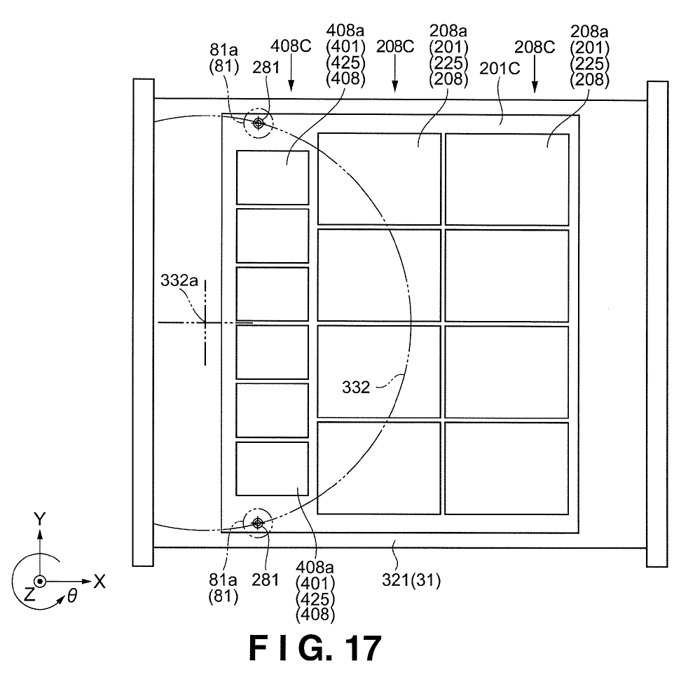

The positional relationship between the rotation center 332a and the arrangement of the CF layers 208 (CF layer regions 208a) and CF layers 408 (CF layer regions 408a) in the mother opposing substrate 201C will next be described with reference to FIG. 17. FIG. 17 is a diagram showing the mother opposing substrate having been mounted on the workpiece mounting stage and θ-adjusted. The X-axis direction, Y-axis direction, Z-axis direction, and θ direction shown in FIG. 17 coincide with the X-axis direction, Y-axis direction, Z-axis direction, and θ direction shown in FIG. 1. A mother opposing substrate in which CF layers 208 and other layers are formed on the mother opposing substrate 201C, or a mother opposing substrate in which the CF layers 208 and other layers are in the process of being formed is referred to as a mother opposing substrate 201C, the same as in the case of the mother opposing substrate 201A and other mother opposing substrate described above.

As shown in FIG. 17, the rotation center 332a is the center of rotation of a θ table 332 provided to a workpiece mounting stage 321 in which the configuration of the rotation device differs from that of the workpiece mounting stage 21. The θ table 332 is configured so that the rotation center 332a is positioned toward the end of the suction table 31 in the primary scanning direction. The θ table 332 corresponds to the rotation device, and the rotation center 332a corresponds to the center of rotation.

The CF layers 208 of the opposing substrate 220 are formed in the mother opposing substrate 201C, and the CF layers 408 that constitute the opposing substrates 420 are formed in the portions that are the glass substrates 401. As described above, the opposing substrates 420 provided with the CF layers 408 have essentially the same structure as the opposing substrates 220 and are opposing substrates for forming liquid crystal display panels that have a smaller surface area than a liquid crystal display panel 200.

A pair of alignment marks 281, 281 the same as those of the mother opposing substrate 201A are formed in positions that are outside the regions in which the CF layers 208 or CF layers 408 are formed in the mother opposing substrate 201C. The alignment marks 281 are used as reference marks for positioning at such times as when the mother opposing substrate 201C is attached to the droplet discharge device 1 or other manufacturing device in order to perform the steps for forming the CF layers 208 and other layers.

In FIG. 17, the gaps between the CF layer regions 208a or CF layer regions 408a are enlarged in order to make the drawing easier to understand, but these gaps are preferably made as small as possible in order to efficiently utilize the mother opposing substrate 201C.

In a state in which the mother opposing substrate 201C prior to arrangement of the functional liquid is mounted substantially in a predetermined position of the workpiece mounting stage 321, the rotation center 332a is at the edge of the side on which the pair of alignment marks 281, 281 are formed in the primary scanning direction of the mother opposing substrate 201C. The CF region rows 208C in which the CF layer regions 208a are arranged in a row, and the CF region rows 408C in which the CF layer regions 408a are arranged in a row extend in the secondary scanning direction. The CF region rows 408C are provided closer to the end at which the alignment marks 281 are formed in the primary scanning direction of the mother opposing substrate 201C than the CF region rows 208C. In the state shown in FIG. 17 in which the mother opposing substrate 201C is mounted substantially in a predetermined position of the workpiece mounting stage 321, the CF region rows 408C are provided in positions closer to the rotation center 32a than the CF region rows 208C.

Positional displacement of the landing target regions due to misalignment of the mother opposing substrate 201C in the θ direction increases as the distance from the rotation center 332a increases, the same as in the case of the mother opposing substrate 201A described above.

The filter film regions 425 of the CF layers 408 (CF layer regions 408a) are smaller than the filter film regions 225 of the CF layers 208 (CF layer regions 208a). Therefore, when the same amount of positional displacement has occurred, defects such as the functional liquid being arranged outside of the intended filter regions are more likely to occur in the filter film regions 425 than in the filter film regions 225.

In the mother opposing substrate 201C, the CF region rows 408C are provided closer to the rotation center 332a than the CF region rows 208C, and the positional displacement of the landing target regions 425E when positional displacement (angle misalignment) in the θ direction occurs after alignment is therefore smaller than the positional displacement of the landing target regions 225E. Consequently, the filter film regions 425, which have a higher likelihood of defects when positional displacement occurs, are arranged in the mother opposing substrate 201C so that the amount of positional displacement is reduced.

The CF layer regions 208a in the mother opposing substrate 201C correspond to first film formation regions, first functional film regions, or first filter regions, and the CF layer regions 408a correspond to second film formation regions, second functional film regions, or second filter regions. The CF region rows 208C correspond to third region rows or third filter region rows, and the CF region rows 408C correspond to fourth region rows or fourth filter region rows. The mother opposing substrate 201C prior to forming the filter films 205 of the CF layers 208 and CF layers 408 corresponds to a mother substrate or mother base plate.

### Fourth Modified Example of CF Layers in Mother Opposing Substrate

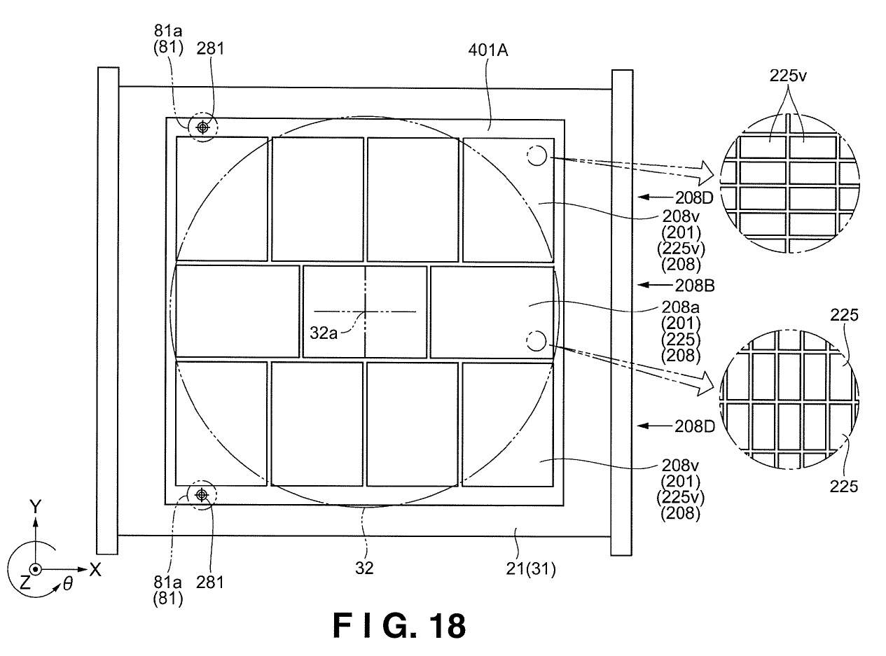

The positional relationship between the rotation center 32a and the arrangement of the CF layers 208 (CF layer regions 208a) and vertically oriented CF layers 208 (CF layer regions 208v) in the mother opposing substrate 401A will next be described with reference to FIG. 18. FIG. 18 is a diagram showing the mother opposing substrate having been mounted on the workpiece mounting stage and θ-adjusted. A manner of arranging the CF layers 208 so that the long-side direction of the CF layers 208 extends in the secondary scanning direction with respect to the mother opposing substrate 401A mounted on the workpiece mounting stage 21 and θ-adjusted is referred to as a vertical orientation. The regions for forming the vertically oriented CF layers 208 in the mother opposing substrate 401A in the state prior to arranging the functional liquid are referred to as CF layer regions 208v, the same as the CF layer regions 208a for the CF layers 208. A mother opposing substrate in which CF layers 208 are formed on the mother opposing substrate 401A, or a mother opposing substrate in which the CF layers 208 are in the process of being formed is referred to as a mother opposing substrate 401A, the same as in the case of the mother opposing substrate 201A and other mother opposing substrate described above.

As shown in FIG. 18, CF layers 208 having different arrangement directions are formed on the mother opposing substrate 401A. A pair of alignment marks 281, 281 the same as those of the mother opposing substrate 201A are formed in positions that are outside the regions in which the CF layers 208 are formed in the mother opposing substrate 401A. The alignment marks 281 are used as reference marks for positioning at such times as when the mother opposing substrate 401A is attached to the droplet discharge device I or other manufacturing device in order to perform the steps for forming the CF layers 208 and other layers.

In FIG. 18, the gaps between the CF layer regions 208a or CF layer regions 208v are enlarged in order to make the drawing easier to understand, but these gaps are preferably made as small as possible in order to efficiently utilize the mother opposing substrate 401A.

In a state in which the mother opposing substrate 401A prior to arrangement of the functional liquid is mounted substantially in a predetermined position of the workpiece mounting stage 21, the rotation center 32a is at the center of the mother opposing substrate 401A. The CF region rows 208B in which the CF layer regions 208a are arranged in a row, and the CF region rows 208D in which the CF layer regions 208v are arranged in a row extend in the primary scanning direction. The CF region rows 208B are provided closer to the center of the mother opposing substrate 401A than the CF region rows 208D. In the state shown in FIG. 18 in which the mother opposing substrate 401A is mounted substantially in a predetermined position of the workpiece mounting stage 21, the CF region rows 208B are provided in positions closer to the rotation center 32a than the CF region rows 208D. The CF layer regions 208a are provided in positions closer to the rotation center 32a than the CF layer regions 208v in the secondary scanning direction.

As described with reference to FIG. 12, the filter film regions 225 of the CF layer regions 208a have an elongated rectangular shape. In the state shown in FIG. 18 in which mother opposing substrate 401A is mounted substantially in a predetermined position on the workpiece mounting stage 21, the filter film regions 225 of the CF layer regions 208a are arranged so that the long sides thereof extend in the secondary scanning direction. The filter film regions 225v of the CF layer regions 208v are essentially the same as the filter film regions 225, but are arranged so that the long sides thereof extend in the primary scanning direction. Therefore, when the same amount of positional displacement occurs in the primary scanning direction, defects such as the functional liquid being arranged outside of the intended filter regions are more likely to occur in the filter film regions 225 than in the filter film regions 225v.

Positional displacement of the landing target regions due to misalignment of the mother opposing substrate 401A in the θ direction increases as the distance from the rotation center 32a increases, the same as in the case of the mother opposing substrate 201A described above. When positional displacement and the direction of the distance from the rotation center 32a are taken into account, the positional displacement in the primary scanning direction due to misalignment in the θ direction increases as the distance from the rotation center 32a in the secondary scanning direction increases, and positional displacement in the secondary scanning direction due to misalignment in the θ direction increases as the distance from the rotation center 32a in the primary scanning direction increases.

In the mother opposing substrate 401A, the CF region rows 208B that extend in the primary scanning direction are provided closer to the rotation center 32a than the CF region rows 208D, and the positional displacement of the filter film regions 225 in the primary scanning direction when positional displacement (angle misalignment) in the θ direction occurs after alignment is therefore smaller than the positional displacement of the filter film regions 225v in the primary scanning direction. The CF layer regions 208a are provided in positions closer to the rotation center 32a in the secondary scanning direction than the CF layer regions 208v, and the positional displacement of the filter film regions 225 in the primary scanning direction when positional displacement (angle misalignment) in the θ directions occurs after alignment is thereby smaller than the positional displacement of the filter film regions 225v in the primary scanning direction. Consequently, the filter film regions 225, which have a higher likelihood of defects when positional displacement occurs in the primary scanning direction, are arranged in the mother opposing substrate 401A so that the amount of positional displacement thereof is less than the positional displacement of the filter film regions 225v in the primary scanning direction.

The filter film regions 225v in the mother opposing substrate 401A correspond to first film formation sections, first functional film partitions, or first color element regions, and the filter film regions 225 correspond to second film formation sections, second functional film partitions, or second color element regions. The CF layer regions 208v correspond to first film formation regions, first functional film regions, or first filter regions, and the CF layer regions 208a correspond to second film formation regions, second functional film regions, or second filter regions. The CF region rows 208D correspond to first region rows or first filter region rows, and the CF region rows 208B correspond to second region rows or second filter region rows. The mother opposing substrate 401A prior to forming the filter films 205 of the CF layers 208 corresponds to a mother substrate or mother base plate.

### Fifth Modified Example of CF Layers in Mother Opposing Substrate

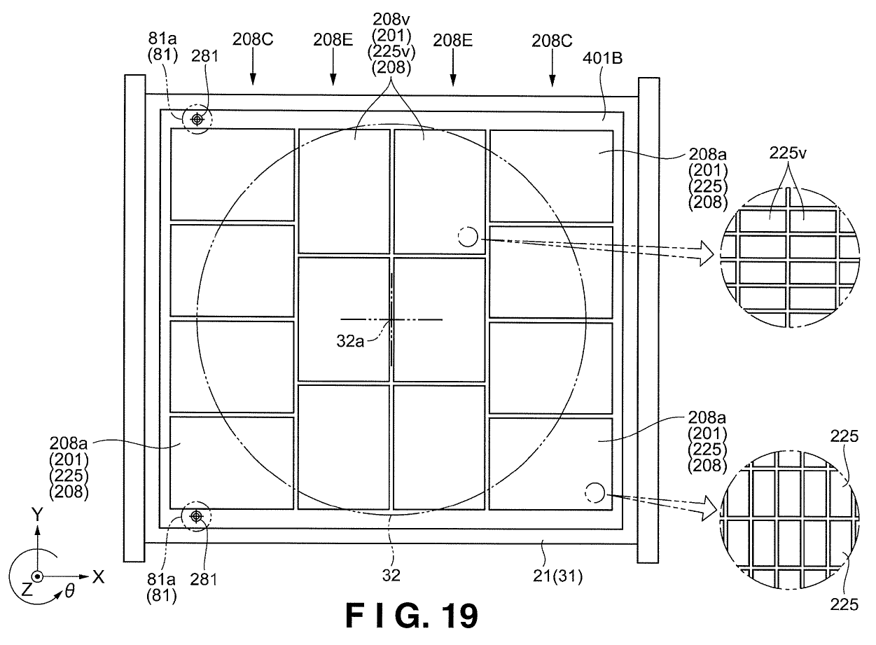

The positional relationship between the rotation center 32a and the arrangement of the CF layers 208 (CF layer regions 208a) and vertically oriented CF layers 208 (CF layer regions 208v) in the mother opposing substrate 401B will next be described with reference to FIG. 19. FIG. 19 is a diagram showing the mother opposing substrate having been mounted on the workpiece mounting stage and θ-adjusted. A manner of arranging the CF layers 208 so that the long-side direction of the CF layers 208 extends in the primary scanning direction with respect to the mother opposing substrate 401B mounted on the workpiece mounting stage 21 and θ-adjusted is referred to as a vertical orientation, the same as in the case of the mother opposing substrate 401A. The regions for forming the vertically oriented CF layers 208 in the mother opposing substrate 401B in the state prior to arranging the functional liquid are referred to as CF layer regions 208v, the same as the CF layer regions 208a for the CF layers 208. A mother opposing substrate in which CF layers 208 are formed on the mother opposing substrate 401B, or a mother opposing substrate in which the CF layers 208 are in the process of being formed is referred to as a mother opposing substrate 401B, the same as in the case of the mother opposing substrate 201A and other mother opposing substrate described above.

As shown in FIG. 19, CF layers 208 having different arrangement directions are formed on the mother opposing substrate 401B. A pair of alignment marks 281, 281 the same as those of the mother opposing substrate 201A are formed in positions that are outside the regions in which the CF layers 208 are formed in the mother opposing substrate 401B. The alignment marks 281 are used as reference marks for positioning at such times as when the mother opposing substrate 401B is attached to the droplet discharge device 1 or other manufacturing device in order to perform the steps for forming the CF layers 208 and other layers.

In FIG. 19, the gaps between the CF layer regions 208a or CF layer regions 208v are enlarged in order to make the drawing easier to understand, but these gaps are preferably made as small as possible in order to efficiently utilize the mother opposing substrate 401B.

In a state in which the mother opposing substrate 401B prior to arrangement of the functional liquid is mounted substantially in a predetermined position of the workpiece mounting stage 21, the rotation center 32a is at the center of the mother opposing substrate 401B. The CF region rows 208C in which the CF layer regions 208a are arranged in a row, and the CF region rows 208E in which the CF layer regions 208v are arranged in a row extend in the secondary scanning direction. The CF region rows 208E are provided closer to the center of the mother opposing substrate 401B than the CF region rows 208C. In the state shown in FIG. 19 in which the mother opposing substrate 401B is mounted substantially in a predetermined position of the workpiece mounting stage 21, the CF region rows 208E are provided in positions closer to the rotation center 32a than the CF region rows 208C. The CF layer regions 208v are provided in positions closer to the rotation center 32a than the CF layer regions 208a in the primary scanning direction.

As described with reference to FIG. 12, the filter film regions 225 of the CF layer regions 208a have an elongated rectangular shape. In the state shown in FIG. 19 in which mother opposing substrate 401B is mounted substantially in a predetermined position on the workpiece mounting stage 21, the filter film regions 225 of the CF layer regions 208a are arranged so that the long sides thereof extend in the secondary scanning direction. The filter film regions 225v of the CF layer regions 208v are essentially the same as the filter film regions 225, but are arranged so that the long sides thereof extend in the primary scanning direction. Specifically, the filter film regions 225 are longer in the secondary scanning direction than the filter film regions 225v. When the same amount of positional displacement occurs in the secondary scanning direction, defects such as the functional liquid being arranged outside of the intended filter regions are more likely to occur in the filter film regions 225v than in the filter film regions 225.

Positional displacement of the landing target regions due to misalignment of the mother opposing substrate 401B in the θ direction increases as the distance from the rotation center 32a increases, the same as in the case of the mother opposing substrate 201A described above. When positional displacement and the direction of the distance from the rotation center 32a are taken into account, the positional displacement in the primary scanning direction due to misalignment in the θ direction increases as the distance from the rotation center 32a in the secondary scanning direction increases, and positional displacement in the secondary scanning direction due to misalignment in the θ direction increases as the distance from the rotation center 32a in the primary scanning direction increases.

In the mother opposing substrate 401B, the CF region rows 208E that extend in the secondary scanning direction are provided closer to the rotation center 32a than the CF region rows 208C, and the positional displacement of the filter film regions 225v in the secondary scanning direction when positional displacement (angle misalignment) in the θ direction occurs after alignment is therefore smaller than the positional displacement of the filter film regions 225 in the secondary scanning direction. The CF layer regions 208v are provided in positions closer to the rotation center 32a in the primary scanning direction than the CF layer regions 208a, and the positional displacement of the filter film regions 225v in the secondary scanning direction when positional displacement (angle misalignment) in the θ directions occurs after alignment is thereby smaller than the positional displacement of the filter film regions 225 in the secondary scanning direction. Consequently, the filter film regions 225v, which have a higher likelihood of defects when positional displacement occurs in the secondary scanning direction, are arranged in the mother opposing substrate 401B so that the amount of positional displacement thereof is less than the positional displacement of the filter film regions 225 in the secondary scanning direction.

The filter film regions 225 in the mother opposing substrate 401B correspond to first film formation sections, first functional film partitions, or first color element regions, and the filter film regions 225v correspond to second film formation sections, second functional film partitions, or second color element regions. The CF layer regions 208a correspond to first film formation regions, first functional film regions, or first filter regions, and the CF layer regions 208v correspond to second film formation regions, second functional film regions, or second filter regions. The CF region rows 208C correspond to third region rows, and the CF region rows 208E correspond to fourth region rows. The mother opposing substrate 401B prior to forming the filter films 205 of the CF layers 208 corresponds to a mother substrate or mother base plate.

The effects of the embodiment will be described below. The following effects are obtained by the present embodiment.

(1) In the mother opposing substrate 201A, the CF region rows 208B in which the CF layer regions 208a are arranged in a row, and the CF region rows 408B in which the CF layer regions 408a are arranged in a row extend in the primary scanning direction. Since the same CF layer regions 208a or CF layer regions 408a extend in the primary scanning direction, the functional liquid can be arranged by driving each droplet discharge head 17 by a specific drive condition during one cycle of relative movement in the primary scanning direction.

(2) In a state in which the mother opposing substrate 201B is mounted substantially in a predetermined position of the workpiece mounting stage 21, CF region rows 208C in which CF layer regions 208a are arranged in a row, and CF region rows 408C in which CF layer regions 408a are arranged in a row extend in the secondary scanning direction. Since the same CF layer regions 208a or CF layer regions 408a extend in the secondary scanning direction, the functional liquid can be arranged by driving the plurality of droplet discharge heads 17 aligned in the secondary scanning direction by the same drive condition. Since the drive condition is uniform, and the speed of relative movement in the primary scanning direction is the same in all of the plurality of droplet discharge heads 17 aligned in the secondary scanning direction, it is possible to prevent the work time from being increased by the need to adapt to droplet discharge heads 17 for which the relative movement is slow.

A preferred embodiment was described above with reference to the drawings, but the preferred embodiments are not limited to the embodiment described above. It is apparent that various modifications may be added to the embodiment in a range that does not depart from the intended scope of the present invention, and such modifications may be implemented as described below.

(Modification 1) In the θ table 32 in the embodiment previously described, the rotation center 32a was provided in a position at the substantial center of the suction table 31, and the rotation center 332a in the θ table 332 was provided in a position toward an end of the suction table 31 in the primary scanning direction. It is not essential that the rotation center of the rotation device be in these positions. The rotation center of the rotation device may be in any position insofar as the position of the mounted substrate or the like in the θ direction can be adjusted. In order to efficiently perform the alignment operation, the rotation center is preferably positioned so as to minimize travel of reference marks such as the alignment marks 281 formed on the substrate or the like when the mounted substrate or the like is rotated to adjust the θ direction. When a pair of reference points is provided, such as in the case of the pair of alignment marks 281, 281, the rotation center is preferably positioned so that the travel of one of the reference points is minimized, or so that the travel of each of the reference points in the pair of reference points is substantially equal.

(Modification 2) In the previously described embodiment, the CF layers 208, CF layers 408, and CF layers 308 had mutually different sizes but the same configuration, but it is not essential that the CF layers and other layers constituting the same mother substrate have the same configuration. The layers may have any configuration insofar as the arranged functional liquids are the same.

(Modification 3) In the previously described embodiment, the CF layers 208 provided to the liquid crystal display panel 200 formed a tricolor filter having three colors of filter films that included red filter films 205R, green filter films 205G, and blue filter films 205B, but the color filter may also be a multicolor color filter having even more types of filter films. Examples of multicolor color filters include a six-color filter having cyan (blue-green), magenta (violet-red), and yellow (yellow) organic EL elements, which are complementary to red, green, and blue, in addition to red, green, and blue; a four-color filter in which green is added to the three colors cyan (blue-green), magenta (violet-red), and yellow (yellow); and the like.

(Modification 4) In the previously described embodiment, drawing discharge to form a filter film 205 of a liquid crystal display panel 200 was described, but the formed film is not limited to a filter film. The formed film may also be a pixel electrode film, an alignment film, or an opposing electrode film of a liquid crystal display device, or an overcoat film or the like provided for such a purpose as protecting a color filter or the like.

The device having the formed film, or the device for which a film must be formed in the formation process is also not limited to a liquid crystal display device. The device may be any device insofar as the device has a film such as described above, or the device is one in which a film such as described above must be formed in the formation process. The present invention may be applied to an organic EL display device, for example. The functional film formed using the droplet discharge device described above when an organic EL display device is manufactured may be the positive electrode film or negative electrode film of the organic EL display device, a film for forming a pattern by photoetching or the like, a photoresist film for photoetching or the like, or another film.

(Modification 5) In the previously described embodiment, a liquid crystal display panel 200 provided with a color filter was described as an example of the drawing subject on which drawing was performed by using a droplet discharge device 1 to arrange a functional liquid, but the drawing subject is not limited to a color filter. The mother substrate, film formation region arrangement method, and color filter manufacturing method described above can be utilized as a mother substrate, film formation region arrangement method for arranging a liquid body, and manufacturing and processing method relating to various processing subjects that are processed by arranging various liquid bodies during manufacturing. For example, the present invention can be used as a mother circuit substrate of a circuit substrate, and a wiring conductor pattern processing method for discharging a liquid conductor material; a mother circuit substrate of a circuit substrate having an insulation film, and an insulation film pattern processing method for discharging a liquid insulation material; a semiconductor wafer and a processing method for a semiconductor device wiring conductor film for discharging a liquid conductor material; a semiconductor wafer and a semiconductor device insulation layer processing method for discharging a liquid insulation material; or the like.

(Modification 6) In the previously described embodiment, the filter film region 225 or the like as a film formation section, functional film partition, or color element region had an elongated rectangular shape, but it is not essential that the film formation section, functional film partition, or color element region have an elongated rectangular shape. Display devices having pixel shapes other than rectangular have recently been proposed for enhancing display characteristics. The film formation sections, functional film partitions, or color element regions may be shaped so that pixel shapes other than rectangular shapes can be formed.

(Modification 7) In the previously described embodiment, the filter film region 225 or the like as the film formation section, functional film partition, or color element region was of the same size and shape in a single film formation region, functional film region, or filter film region. However, it is not essential that the film formation section, functional film partition, or color element region have a single size and shape in a single film formation region, functional film region, or filter film region. For example, the film formation region, functional film region, or filter film region may have film formation sections, functional film partitions, or color element partitions of different sizes, in which the size of each color of color element that forms the smallest display unit in a four-color filter is varied according to the characteristics of the light source.

(Modification 8) In the previously described embodiment, the mother opposing substrate 201A or other mother opposing substrate as the mother substrate or mother base plate was provided with two types of film formation regions such as the CF layer regions 208a and the CF layer regions 408a, each having different filter film regions such as the filter film regions 225 or the filter film regions 425. However, it is not essential that the mother substrate or mother base plate have two types of film formation regions. A configuration may also be adopted in which the mother substrate or mother base plate has three or more types of film formation regions having different film formation sections, functional film partitions, or color element regions.

(Modification 9) In the previously described embodiment, the droplet discharge device 1 arranged the functional liquid in the CF layer regions 208a, the CF layer regions 408a, or the like by moving the workpiece mounting stage 21 on which the mother opposing substrate 201A or the like was mounted in the primary scanning direction, and causing the functional liquid to be discharged from the droplet discharge heads 17. The droplet discharge heads 17 (discharge nozzles 78) were also positioned with respect to the mother opposing substrate 201A or the like by moving the head unit 54 in the secondary scanning direction. However, the droplet discharge heads as the arrangement heads, and the mother substrate or mother base plate are not necessarily moved relative to each other in the primary scanning direction by moving the mother substrate or mother base plate, or moved relative to each other in the secondary scanning direction by moving the arrangement heads.

The arrangement heads and the mother substrate or mother base plate may be moved relative to each other in the primary scanning direction by moving the arrangement heads in the primary scanning direction. The arrangement heads and the mother substrate or mother base plate may also be moved relative to each other in the secondary scanning direction by moving the mother substrate or mother base plate in the secondary scanning direction. Alternatively, the arrangement heads and the mother substrate or mother base plate may be moved relative to each other in the primary scanning direction and the secondary scanning direction may moving any one of the arrangement heads and the mother substrate or mother base plate in the primary scanning direction and the secondary scanning direction, or by moving both the arrangement heads and the mother substrate or mother base plate in the primary scanning direction and the secondary scanning direction.

(Modification 10) In the previously described embodiment, a droplet discharge device 1 provided with inkjet-type droplet discharge heads 17 was described as an example of the film formation apparatus for arranging the functional liquid on the mother opposing substrate 201A or the like, but the film formation apparatus is not necessarily a droplet discharge device. A discharge device or the like provided with a dispenser, for example, may also be used as the film formation apparatus. When there is a need to arrange a large quantity of film material in a film formation section having a large surface area, a dispenser that discharges a large quantity per unit time is more useful than a droplet discharge head.

### General Interpretation of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A mother substrate for forming a plurality of substrate elements comprising:
a first film formation region corresponding to a first substrate element and including at least one first film formation section; and
a second film formation region corresponding to a second substrate element and including at least one second film formation section, the second film formation section having a film formation surface area that is smaller than a film formation surface area of the first film formation section,
the second film formation region being disposed in a position closer to a center of rotation of the mother substrate than the first film formation region when the mother substrate is placed on a rotation device of a film formation apparatus during arrangement of a film material on the mother substrate.

2. The mother substrate according to claim 1, wherein
the first and second film formation sections are configured and arranged to receive the film material discharged from an arrangement head for arranging the film material while the arrangement head and the mother substrate move relative to each other in a primary scanning direction,
the first film formation section has a first width in the primary scanning direction and the second film formation section has a second width that is smaller than the first width in the primary scanning direction, and
the second film formation region is disposed in a position closer to the center of rotation of the mother substrate than the first film formation region in a secondary scanning direction that is generally perpendicular to the primary scanning direction.

3. The mother substrate according to claim 1, wherein
the first and second film formation sections are configured and arranged to receive the film material discharged from an arrangement head for arranging the film material while the arrangement head and the mother substrate move relative to each other in a primary scanning direction,
the first film formation section has a third width in a secondary scanning direction generally perpendicular to the primary scanning direction, and the second film formation section has a fourth width that is smaller than the third width in the secondary scanning direction, and
the second film formation region is disposed in a position closer to the center of rotation of the mother substrate than the first film formation region in the primary scanning direction.

4. The mother substrate according to claim 1, wherein
the second film formation region is disposed in a position closer to a center of the mother substrate than the first film formation region.

5. The mother substrate according to claim 2, further comprising
an additional first film formation region aligned with the first film formation region in the primary scanning direction to form a first region row, and
an additional second film formation region aligned with the second film formation region in the primary scanning direction to form a second region row,
the second region row being disposed in a position closer to the center of rotation than the first region row in the secondary scanning direction when the mother substrate is placed on the rotation device.

6. The mother substrate according to claim 5, wherein
the second region row is disposed in a position closer to a center of the mother substrate than the first region row.

7. The mother substrate according to claim 3, further comprising
an additional first film formation region aligned with the first film formation region in the secondary scanning direction to form a third region row, and
an additional second film formation region aligned with the second film formation region in the secondary scanning direction to form a fourth region row,
the fourth region row being disposed in a position closer to the center of rotation than the third region row in the primary scanning direction when the mother substrate is placed on the rotation device.

8. The mother substrate according to claim 7, wherein
the fourth region row is disposed in a position closer to the center of the mother substrate than the third region row.

9. A method for arranging a plurality of film formation regions in a mother substrate for forming a plurality of substrate elements comprising:
providing a first film formation region corresponding to a first substrate element and including at least one first film formation section on the mother substrate; and
providing a second film formation region corresponding to a second substrate element including at least one second film formation section on the mother substrate, the second film formation section having a film formation surface area that is smaller than a film formation surface area of the first film formation section,
the providing of the second film formation region including arranging the second film formation region in a position closer to a center of rotation of the mother substrate than the first film formation region when the mother substrate is placed on a rotation device of a film formation apparatus during arrangement of a film material on the mother substrate.

10. The film formation region arrangement method according to claim 9, wherein
the providing of the first and second film formation regions includes arranging the first and second film formation sections on the mother substrate to receive the film material discharged from an arrangement head for arranging the film material while the arrangement head and the mother substrate move relative to each other in a primary scanning direction,
the providing of the first and second film formation regions includes providing the first film formation section with a first width in the primary scanning direction and the second film formation section with a second width that is smaller than the first width in the primary scanning direction, and
the providing of the first and second film formation regions includes arranging the second film formation region in a position closer to the center of rotation of the mother substrate than the first film formation region in a secondary scanning direction that is generally perpendicular to the primary scanning direction.

11. The film formation region arrangement method according to claim 9, wherein
the providing of the first and second film formation regions includes arranging the first and second film formation sections on the mother substrate to receive a film material discharged from an arrangement head for arranging the film material while the arrangement head and the mother substrate move relative to each other in a primary scanning direction,
the providing of the first and second film formation regions includes providing the first film formation section with a third width in a secondary scanning direction generally perpendicular to the primary scanning direction, and the second film formation section with a fourth width that is smaller than the third width in the secondary scanning direction, and
the providing of the first and second film formation regions includes arranging the second film formation region in a position closer to the center of rotation of the mother substrate than the first film formation region in the primary scanning direction.

12. The film formation region arrangement method according to claim 9, wherein
the providing of the first and second film formation regions includes arranging the second film formation region in a position closer to a center of the mother substrate than the first film formation region.

13. The film formation region arrangement method according to claim 10, further comprising
providing an additional first film formation region aligned with the first film formation region in the primary scanning direction to form a first region row on the mother substrate, and
providing an additional second film formation region aligned with the second film formation region in the primary scanning direction to form a second region row on the mother substrate,
the providing of the first and second film formation regions and the additional first and second film formation regions including arranging the second region row in a position closer to the center of rotation than the first region row in the secondary scanning direction when the mother substrate is placed on the rotation device.

14. The film formation region arrangement method according to claim 13, wherein
the providing of the first and second film formation regions and the additional first and second film formation regions includes arranging the second region row in a position closer to the center of the mother substrate than the first region row.

15. The film formation region arrangement method according to claim 11, further comprising
providing an additional first film formation region aligned with the first film formation region in the secondary scanning direction to form a third region row on the mother substrate, and
providing an additional second film formation region aligned with the second film formation region in the secondary scanning direction to form a fourth region row on the mother substrate,
the providing of the first and second film formation regions and the additional first and second film formation regions including arranging the fourth region row in a position closer to the center of rotation than the third region row in the primary scanning direction when the mother substrate is placed on the rotation device.

16. The film formation region arrangement method according to claim 15, wherein
the providing of the first and second film formation regions and the additional first and second film formation regions includes arranging the fourth region row in a position closer to the center of the mother substrate than the third region row.

17. A color filter manufacturing method comprising:
forming a first color element film in a first color element section of a first filter region on a mother substrate; and
forming a second color element film in a second color element section of a second filter region with the second color element film having a surface area that is smaller than a surface area of the first color element film,
the forming of the first and second color element films including arranging the second filter region in a position closer to a center of rotation of the mother substrate than the first filter region when the mother substrate is placed on a rotation device of a film formation apparatus during arrangement of a film material on the mother substrate.

18. The color filter manufacturing method according to claim 17, wherein
the forming of the first and second color element films includes discharging the film material onto the mother substrate from an arrangement head for arranging the film material while the arrangement head and the mother substrate move relative to each other in a primary scanning direction,
the forming of the first and second color element films further includes forming the first color element film with a first width in the primary scanning direction and the second color element film with a second width that is smaller than the first width in the primary scanning direction, and
the forming of the first and second color element films includes forming the second color element film in a position closer to the center of rotation of the mother substrate than the first color element film in a secondary scanning direction that is generally perpendicular to the primary scanning direction.

19. The color filter manufacturing method according to claim 17, wherein
the forming of the first and second color element films includes discharging the film material from an arrangement head for arranging the film material while the arrangement head and the mother substrate move relative to each other in a primary scanning direction,
the forming of the first and second color element films further includes forming the first color element film with a third width in a secondary scanning direction generally perpendicular to the primary scanning direction, and the second color element film with a fourth width that is smaller than the third width in the secondary scanning direction, and
the forming of the first and second color element films includes forming the second color element film in a position closer to the center of rotation of the mother substrate than the first color element film in the primary scanning direction.

20. The color filter manufacturing method according to claim 17, wherein
the forming of the first and second color element films includes arranging the first and second color element films on the mother substrate so that the second filter region is disposed in a position closer to the center of the mother substrate than the first filter region.

21. The color filter manufacturing method according to claim 18, further comprising
forming an additional first color element film in an additional first color element section of an additional first filter region aligned with the first filter region in the primary scanning direction to form a first filter region row, and
forming an additional second color element film in an additional second color element section of an additional second filter region aligned with the second filter region in the primary scanning direction to form a second filter region row,
the forming of the first and second color element films and the additional first and second color element films including arranging the second filter region row in a position closer to the center of rotation than the first filter region row in the secondary scanning direction when the mother substrate is placed on the rotation device.

22. The color filter manufacturing method according to claim 21, wherein
the forming of the first and second color element films and the additional first and second color element films includes arranging the second filter region row in a position closer to the center of the mother substrate than the first filter region row.

23. The color filter manufacturing method according to claim 19, further comprising
forming an additional first color element film in an additional first color element section of an additional first filter region aligned with the first filter region in the secondary scanning direction to form a third filter region row, and
forming an additional second color element film in an additional second color element section of an additional second filter region aligned with the second filter region in the secondary scanning direction to form a fourth filter region row,
the forming of the first and second color element films and the additional first and second color element films including arranging the fourth filter region row in a position closer to the center of rotation than the third filter region row in the primary scanning direction when the mother substrate is placed on the rotation device.

24. The color filter manufacturing method according to claim 23, wherein
the forming of the first and second color element films and the additional first and second color element films includes arranging the fourth filter region row in a position closer to the center of the mother substrate than the third filter region row.

25. The color filter manufacturing method according to claim 17, further comprising
dividing the mother substrate into the first filter region and the second filter region so that the first filter region forms a first substrate element and the second filter region forms a second substrate element.
